(19) United States
(12) Patent Application Publication
(10) Pub. No.: US 2016/0192079 A1
(43) Pub. Date: Jun. 30, 2016

(54) ROTARY FLUX ACOUSTIC TRANSDUCER

(71) Applicant: Knowles IPC (M) Sdn. Bhd., Penang (MY)

(72) Inventor: Friedrich Reining, Vienna (AT)

(21) Appl. No.: 14/983,875

(22) Filed: Dec. 30, 2015

Related U.S. Application Data
(60) Provisional application No. 62/098,981, filed on Dec. 31, 2014.

(51) Int. Cl. H04R 9/06; H04R 9/04; H04R 7/10; H04R 7/04; H04R 7/20; H03F 3/187; H02K 41/035; H04R 9/02

(52) U.S. Cl. CPC H04R 9/06; H02K 41/0356; H04R 9/045; H04R 9/027; H04R 7/04; H04R 7/20; H03F 3/187; H04R 7/10; H03F 2200/03

(57) ABSTRACT

An electroacoustic transducer assembly may comprise one or more magnets, one or more magnetic flux conductors, and an acoustic membraneplate. The membraneplate, magnets, and flux conductors may be arranged so that a magnet or flux conductor is above the membraneplate and a magnet or flux conductor is below the membraneplate. The magnets and flux conductors may be arranged and polarized such that magnetic flux propagates in a continuous rotary path around the membraneplate.

### PRIORITY

This patent application claims priority from provisional U.S. patent application No. 62/098,981, filed Dec. 31, 2014, entitled, “Rotary Flux Acoustic Transducer,” the disclosure of which is incorporated herein, in its entirety, by reference.

### BACKGROUND

a. Technical Field

The present invention generally relates to acoustic transducer assemblies, including acoustic transducer assemblies incorporating rotary conduction of magnetic flux.

b. Background Art

The basic principle of a speaker is to move a membrane with an electromagnetic coil to generate sound that corresponds to the current flowing through the coil. The force applied to the membrane by the coil is dependent on the number of windings in the coil. For a given impedance and a given space in the air gap through which the coil moves, a certain number of windings can be applied, which contribute to the mass of the voice coil. Thus, an important boundary condition for a loudspeaker is the coil impedance. The sound pressure level (a metric that correlates with the performance of the speaker) correlates with the acceleration of the membrane, which is related to both the force applied by the coil and the mass of the coil. Accordingly, the tradeoffs between the mass of the coil, the number of windings in the coil, and the amount of space dedicated to the speaker must be considered to achieve an optimal sound pressure level.

Requirements for electroacoustic transducers continuously include reducing size while simultaneously increasing performance. In order to keep up with such demands, transducers must be optimized for maximum performance in minimum space. Known transducers are generally based on HiFi-loudspeakers, where space is not the limiting boundary condition, and thus known transducers may not properly optimize performance in a given amount of space.

### BRIEF SUMMARY

It is an object of the invention to have an improved design for electroacoustic transducers generally, and in particular an improved design for micro loudspeakers. It is a further object of the invention to have an electroacoustic transducer having fewer parts than in a traditional transducer design. It is another object of the invention to have a design for an electroacoustic transducer that accommodates both side ports or front ports for air-flow and allows for a greater volume of magnetic material than in an equivalently-sized traditional transducer. Further objects and benefits of the invention are evident from the discussion below and the detailed description contained herein.

An embodiment of an acoustic transducer assembly may comprise a first magnet, a second magnet or a first magnetic flux conductor, and an acoustic membraneplate. The membraneplate may be disposed between (i) the first magnet and (ii) the second magnet or first magnetic flux conductor, and an axis that is perpendicular to the surface of the membraneplate may extend through (i) the first magnet and (ii) the second magnet or first magnetic flux conductor. The first magnet, second magnet, and/or first magnetic flux conductor may be arranged and polarized such that magnetic flux propagates in a continuous rotary path around the membrane.

Another embodiment of an acoustic transducer assembly may comprise two magnets, two magnetic flux conductors, an acoustic membraneplate and two coils. The acoustic membraneplate is configured for excursion along an axis perpendicular to its surface, with the two magnets disposed on opposite surfaces of the acoustic membraneplate along its axis of excursion. The two magnets and the acoustic membraneplate are arranged in substantially parallel planes and may have substantially similar transverse cross-sectional dimensions. The two magnets may also have the same or substantially similar thickness in the direction of the axis of excursion. The two magnetic flux conductors are disposed on opposite edges of the two magnets and may have half crescent or bracket shapes. The magnets may be polarized in a direction that is transverse to the excursion axis of the acoustic membraneplate and parallel to the surface of the membraneplate, with the two magnets having opposite polarization. In such an arrangement, a magnetic flux is generated that travels in a rotary path between the two magnets via the two magnetic flux conductors. Two air gaps may exist, one on each end of the two magnets between the magnets and the magnetic flux conductors. A coil is disposed within each of the two air gaps. Each of the two coils may comprise coil loops wound in a plane that is parallel to the excursion axis of the acoustic membraneplate. The coils are mechanically coupled to the membraneplate, each on opposite end of the membraneplate, so as to move with the membraneplate.

As used herein, a transverse cross-section of the membraneplate means a cross-section in a horizontal plane that is substantially perpendicular to the axis of excursion of the membraneplate.

Another embodiment of an acoustic transducer assembly may comprise a membraneplate having a central axis, an upper axial surface, and a lower axial surface, and a coil. The coil may be mechanically coupled to the membraneplate so as to move with the membraneplate. The coil may extend above the upper axial surface of the membraneplate and below the lower axial surface of the membraneplate. The coil may be arranged such that magnetic flux propagating in a continuous rotary path passes through the coil substantially perpendicular to the windings of the coil.

Another embodiment of an acoustic transducer may comprise a magnet, a coil, and a membraneplate. The membrane may be mechanically coupled with the coil so that the coil is moveable relative to the magnet. An edge of the membraneplate may be fixed relative to the magnet.

Another embodiment of an acoustic transducer may comprise one or more magnets, the magnets having a substantially similar shape and thickness and arranged in a non-parallel configuration, where the space between the two magnets at a first end is less than the space between the two magnets at an opposite second end. The acoustic membraneplate is disposed between the magnets and is configured for excursion along an axis perpendicular to its surface. The magnets are polarized in a direction substantially perpendicular to the excursion axis of the membraneplate. A first magnetic flux conductor is disposed at the first end of the magnets while a second magnetic flux conductor, larger than the first, is disposed at the second end of the magnets. The magnetic flux conductors may have half crescent or bracket shapes. The membraneplate is pivotally fixed at the edge near the first end of the magnets. The edge of the membraneplate may be coupled to the first magnetic flux conductor by being clamped, attached to a suspension, or a number of other mechanical coupling configurations. A coil is disposed in an air gap existing between the second magnetic flux conductor and the second end of the magnets. The coil is attached to the membraneplate and moves through the air gap. This configuration may be referred to as a reed-type rotary flux transducer.

In another embodiment an acoustic transducer may comprise an acoustic membraneplate configured for excursion along an axis perpendicular to its surface, two magnets polarized in the same direction and disposed on the same side of the membraneplate. A first magnetic flux conductor comprises a first crescent portion and a first planar portion, disposed at a first end of the membraneplate and on the side of the membraneplate opposite the magnets, respectfully. The first end of the membraneplate is pivotally fixed by, for example, being coupled to the first crescent portion. A second magnetic flux conductor comprises a second crescent portion and a second planar portion, disposed at a second end of the membraneplate and on the side of the membraneplate opposite the magnets, respectfully. The first planar portion and second planar portion together are substantially the same length as the two magnets together. The two magnets and two magnetic flux conductors thus create a rotary flux path around the membraneplate. An air gap exists between the magnets on one side of the membraneplate and between the two planner portions on the other side of the membraneplate. A coil is disposed in the air gap and is coupled to a middle portion of the membraneplate. The two magnets may be the same length or may be of different lengths. Likewise, the two planar portions may have the same or different lengths. Thus, in various embodiments, the location of the air gap, and thus the location of the coil, may be provided at any distance relative to the pivotally fixed end of the membraneplate.

Another embodiment of an acoustic transducer may comprise two coils. The coils are wound separately and have a generally planar portion along substantially their entire lengths. At one end of each coil there is a generally off-plane portion angled off from the planar portion. The off-plane portion allows the planar portions of each coil to be in substantially the same plane when the coils are placed together. The coils may be joined together in such configuration by adhesive or other attachment means. The joined coils may then be used in the various embodiments of a rotary flux transducer described herein in the same manner as a single coil. One of the advantages of a double coil configuration for a speaker transducer is that the coils can be connected to the same or different driver circuits.

Another embodiment of an acoustic transducer may comprise a membraneplate, one or more coils and a rotary flux circuit assembly comprising at least a first magnet and at least one of (i) a second magnet or (ii) a magnetic flux conductor, the rotary flux circuit configured to generate a magnetic flux in a rotary pattern around the membraneplate. The membrane may be mechanically coupled with the coil so that the coil is moveable relative to the first magnet. The transducer may further comprise an integrated circuit disposed on the membraneplate or coupled to an edge of the membraneplate. The integrated circuit may be an amplifier, buffer, analog-to-digital converter or other known electrical circuit useful in acoustic transducer applications. In an embodiment, the circuit may comprise an amplifier and an electrical output damping portion. The amplifier may be a class D amplifier and may be printed on the surface of the membraneplate using known methods. The electrical output damping portion is electrically coupled between the amplifier and the coil, such that it receives the output signal of the amplifier and outputs a damped version of that signal for input to the coil. The electrical output damping portion may be ferrite beads or another electrical damping component, and may be disposed on or coupled with an edge of the membraneplate.

Another embodiment of an acoustic transducer may comprise a reinforced membraneplate. The membraneplate may comprise a core layer and outer layers on opposed sides of the core layer. The core layer may have a foam matrix and the outer layers may be comprised of a metal laminate, such as an aluminum laminate. The membraneplate may be symmetric along an axis in the direction of excursion such that the two outer layers are of the same material and dimensions. The membraneplate may include one or more features for anisotropic reinforcement along a length of the membraneplate. The membraneplate may include a plurality of flanges disposed in the core layer. Some or all of the flanges may be parallel or substantially parallel with each other. The flanges may comprise metal, such as aluminum, and may be the same material as one or both the outer layers. One or more, or all of the flanges may comprise a continuous piece of monolithic material extending along the entire length of the membraneplate, Alternatively, one or more of the flanges may comprise a piece of material that extends along only a portion of the length of the membraneplate. In another embodiment, instead of flanges, a reinforced membraneplate may include anisotropic reinforcement through a plurality of fibers generally oriented along a length of the membraneplate. The fibers may comprise metal or another appropriate material. A reinforced membraneplate is particularly beneficial in a reed-type rotary flux transducer as described herein due to the particular stress distribution in the membraneplate.

Another embodiment of an acoustic transducer may comprise one or more magnets, zero, one or more magnetic flux conductors, a membraneplate and at least one coil, arranged such that a magnetic flux is propagated in a rotary path around the membraneplate, with the one or more coils being disposed within the magnetic flux path. The acoustic transducer may further comprise a housing for containing the components of the acoustic transducer. The housing may further have indentations corresponding to the shape of the one or more magnetic flux conductors and may be directly connected to the magnetic flux conductors. The housing may further contain air holes or vents to facilitate air flow from outside of the housing to one or both axial sides of the membraneplate. The air holes or vents may be on a top or bottom of the housing, or in a side of the housing, thus accommodating front-firing or side-firing transducer arrangements.

### BRIEF DESCRIPTION OF THE DRAWINGS

These and other aspects, features, details, utilities, and advantages of the invention will become more fully apparent from the following detailed description, appended claims, and accompanying drawings, wherein the drawings illustrate features in accordance with exemplary embodiments of the invention, and wherein:

FIG. 1 is a diagrammatic view of an embodiment of a prior art acoustic transducer assembly.

FIG. 2 is a cross-sectional view of another embodiment of a prior art acoustic transducer assembly.

FIG. 3 is an isometric view of a portion of an embodiment of a rotary flux acoustic transducer assembly.

FIG. 4 is an isometric view of a portion of the rotary flux acoustic transducer assembly illustrated in FIG. 3.

FIG. 5 is a cross-sectional view of the rotary flux acoustic transducer assembly portion of FIG. 4, diagrammatically illustrating the rotary propagation of magnetic flux.

FIG. 6 is an isometric view of an embodiment of a rotary flux acoustic transducer assembly with a portion of a housing shown in phantom.

FIG. 7 is an isometric view of the rotary flux acoustic transducer assembly of FIG. 6.

FIG. 8 is an isometric view of an embodiment of a rotary flux acoustic transducer assembly.

FIG. 9 is an isometric view of an embodiment of a rotary flux acoustic transducer assembly.

FIG. 10 is an isometric view of an embodiment of a rotary flux acoustic transducer assembly.

FIG. 11 is an isometric view of an embodiment of a rotary flux acoustic transducer assembly.

FIG. 12 is an isometric view of an embodiment of a rotary flux acoustic transducer assembly.

FIGS. 13 and 14 are isometric views of an embodiment of a rotary flux acoustic transducer assembly, with a housing shown in phantom.

FIG. 15a is an isometric view of an embodiment of a rotary flux acoustic transducer assembly, with a housing shown in phantom.

FIG. 15b is an enlarged isometric view of a portion of the rotary flux acoustic transducer assembly portion of FIG. 15a, with the housing shown in phantom.

FIGS. 16a-16d are isometric views of alternative embodiments of a rotary flux acoustic transducer assembly.

FIG. 17 is an isometric view of an embodiment of a rotary flux acoustic transducer assembly having two coils.

FIGS. 18-22 are isometric views of the rotary flux acoustic transducer assembly portion of FIG. 17 at various stages of manufacture.

FIG. 23 is a diagrammatic view of an assembly including an amplifier printed on a membrane that may find use in a rotary flux acoustic transducer assembly.

FIG. 24 is an isometric view of an exemplary embodiment of an assembly including a membraneplate coupled with a coil that may find use in a rotary flux acoustic transducer assembly.

FIG. 25 is a partial isometric view of an exemplary embodiment of an assembly including a membraneplate having flanges coupled with a coil that may find use in a rotary flux acoustic transducer assembly.

FIG. 26 is a partial isometric view of the assembly of FIG. 25 implemented in an exemplary embodiment of a reed-style rotary flux transducer assembly.

FIG. 27 is a partial isometric view of an exemplary embodiment of an assembly including a membraneplate, a cap, and a coil that may find use in a rotary flux acoustic transducer assembly.

### DETAILED DESCRIPTION

### Traditional Electroacoustic Transducer Assembly

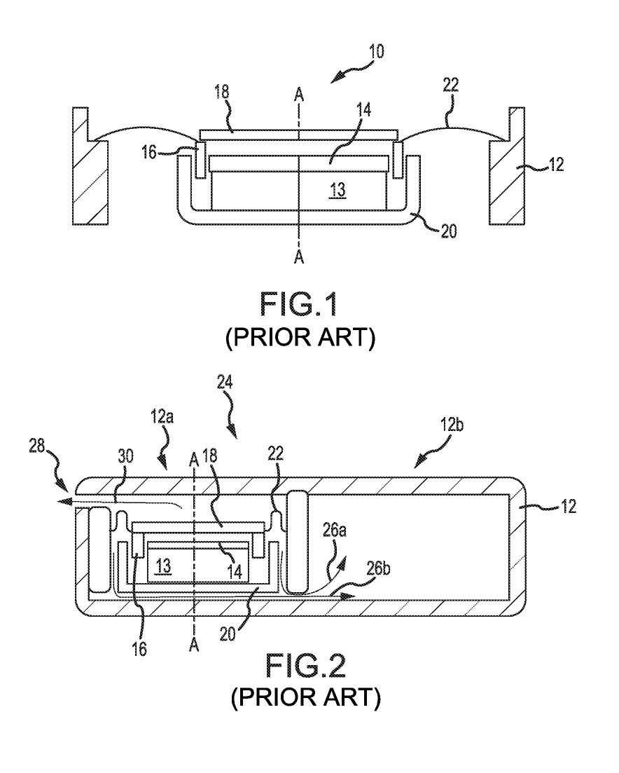

Referring to the drawings, wherein like reference numerals refer to the same or similar features in the various views, FIG. 1 is a cross-sectional view of a known first embodiment of an electroacoustic transducer assembly 10 that will be used to illustrate the basic functionality of an electroacoustic transducer. For the remainder of this disclosure, electroacoustic transducers, the applications in which they are implemented, or portions thereof, may be referred to as acoustic transducer assemblies, transducer assemblies, acoustic transducers, or simply as transducers. It should be understood that any of these terms, as used herein, may encompass more or fewer elements than are necessary to translate acoustic waves into electrical signals, or vice-versa. For example, what may be referred to in the art as a transducer assembly “application,” including the mechanical components needed for a functioning acoustic device in addition to the components necessary for transduction, may also be referred to herein as a transducer or transducer assembly.

The transducer 10 may include a housing 12, a stationary magnet 13, a top-plate 14, an electromagnetic coil 16, a membraneplate 18, and a pot 20. The membraneplate 18 may be coupled to the coil 16 and/or to the suspension 22, which may be coupled with the housing 12, in an embodiment, and the membraneplate 18, the suspension 22, and the coil 16 may be moveable relative to the stationary magnet 13 along the central axis A of the membraneplate 18. The membraneplate 18 and suspension 22, in combination, may define a membrane. In an embodiment in which the transducer 10 is used in a speaker, an electrical current may be fed into the coil 16, which current may interact with a magnetic field (according to the Lorentz force) produced by the stationary magnet 14 so as to move the coil 16 and membraneplate 18 relative to the stationary magnet 13, whereby the membraneplate 18 and the suspension 22 may produce an acoustic pressure wave. The pot 20 and top plate 14 may conduct magnetic flux from the stationary magnet 13.

The membraneplate 18 may be mechanically coupled with the suspension 22 for mechanically coupling the membraneplate 18 with the housing, in an embodiment. The suspension 22 may be provided at an outer radial portion of the membraneplate 18. The membraneplate 18 may be suspended around its full circumference, in an embodiment (i.e., may be a fully-suspended membraneplate).

The transducer 10 may find use, for example only, as a part of a microphone and/or speaker, in an embodiment, in any appropriate application. For example, the transducer 10 may find use in a mobile phone or other mobile or portable device, in an embodiment. Other transducer assemblies described and/or illustrated herein may have similar uses.

FIG. 2 is a cross-sectional view of a known second embodiment of an acoustic transducer assembly 24, which may be referred to as a “sideport” design. The transducer 24 is similar to the transducer 10 of FIG. 1, but the membraneplate 18, coil 16, magnet 13, top plate 14, and pot 20 may be disposed in a first housing portion 12a, and the housing 12 may further include a second housing portion 12b provided for receiving airflow (represented as arrows 26a, 26b) displaced by membraneplate excursion. The second housing portion 12b may be provided to the radial side (i.e., as used herein, “axial” and “radial” should be understood to refer to directions relative to the central axis A of the subject membraneplate unless clearly indicated otherwise) or lateral side of the first housing portion 12a. Such a housing 12 may be provided for a mobile transducer, in which lateral space is more readily available than axial space (e.g., due to a desire to minimize the thickness of the mobile device).

The sideport transducer assembly 24 also includes an air inlet/outlet 28 that is disposed radially from the direction of membraneplate excursion. As a result, air flowing in towards the membraneplate 18 (in a microphone embodiment) or out from the membraneplate (in a speaker embodiment; represented by arrow 30) must move perpendicular to the direction of excursion of the membraneplate 18.

Rotary Flux Electroacoustic Transducer Assembly.

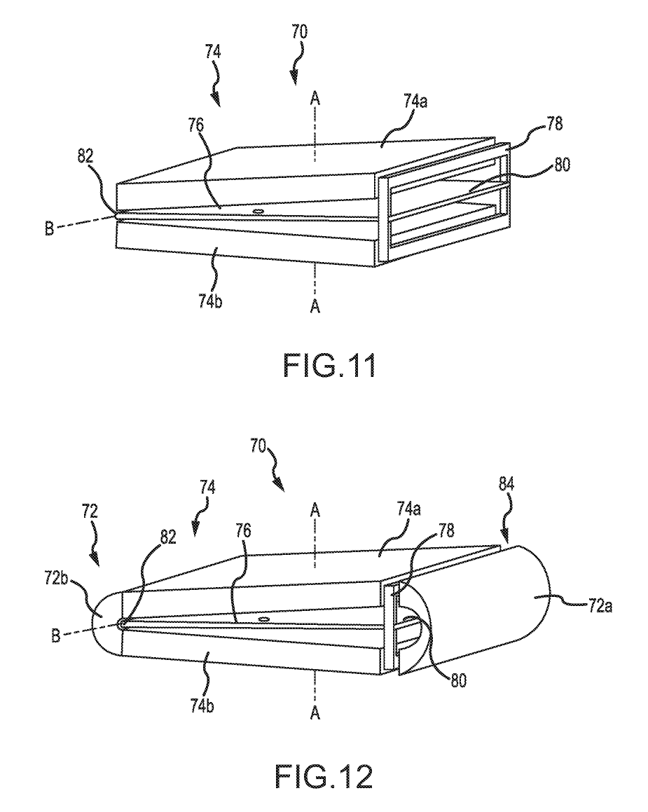

A configuration for an electroacoustic transducer that improves on known transducers may include rotary conduction of magnetic flux around the membraneplate and may be referred to as a rotary flux transducer. As set forth below, embodiments of a rotary flux transducer may optimize the performance/space ratio by minimizing the usage of soft iron as a flux conductor and may store more magnetic energy in the same available space relative to a known transducer. A particular type of rotary flux transducer, referred to herein as a reed-style transducer, may maximize performance by gaining more coil acceleration with less membraneplate displacement, thus requiring less space. Exemplary embodiments of reed-style transducer assemblies are illustrated in and will be described with respect to FIGS. 11-17 and 25-27.

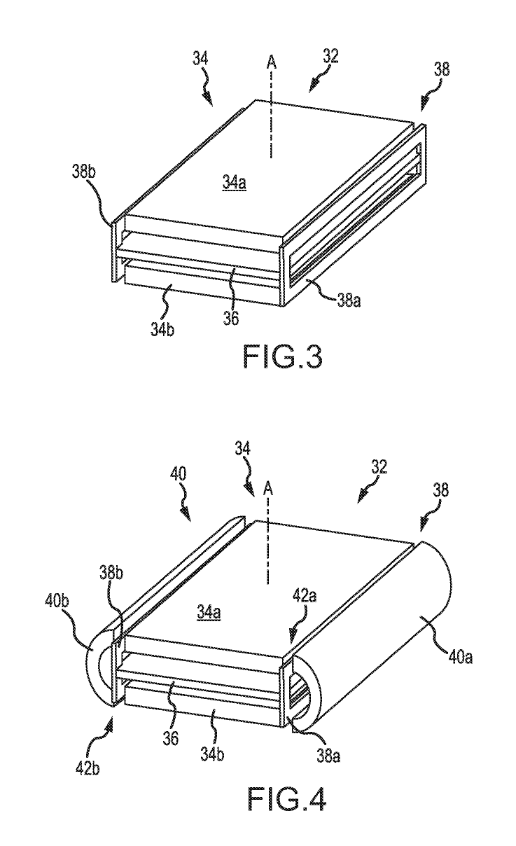

FIG. 3 is an isometric view of an embodiment of a rotary flux acoustic transducer assembly 32. The rotary flux transducer assembly 32 may include a magnet 34 (two magnet portions 34a, 34b are shown in FIG. 3), a membraneplate 36, and one or more coils 38 (two such coils 38a, 38b are shown in FIG. 3). The membraneplate 36 may be configured for excursion along an axis A, and may be rectangular, circular, or have some other shape (i.e., may have a rectangular, circular, or some other cross-section transverse to the axis A).

The magnet 34 may include two or more magnet portions, in an embodiment. The magnet may include a first portion 34a and a second portion 34b, with the first portion 34a and the second portion 34b disposed on opposite radial sides of the membraneplate 36. The magnet portions 34a, 34b may have transverse cross-sectional dimensions that are the same as or similar to each other, in an embodiment, and that are the same as or similar to the membraneplate, in an embodiment. The magnet portions 34a, 34b may additionally have the same or similar respective axial thicknesses, in an embodiment. The magnet portions 34a, 34b may be parallel to each other, and may be parallel to the surface of the membraneplate 36, in an embodiment. The magnet portions 34a, 34b may be polarized in a direction that is transverse to the axis A of the membraneplate 36 (i.e., transverse to the direction of excursion of the membraneplate 36) and is parallel to the surface of the membraneplate 36, in an embodiment.

One or more of the magnet portions 34a, 34b may have a cuboid shape, in an embodiment. Cuboid magnets are generally inexpensive, and thus cuboid magnet portions 34a, 34b may help maintain a lower manufacturing cost of the transducer. Additionally or alternatively, one or more magnet portions 34a, 34b may have a shape other than a cuboid, in an embodiment.

The coil 38 may include two or more portions, in an embodiment. For example, as shown in FIG. 3, the coil may include two portions 38a, 38b disposed on opposite radial sides of the membraneplate 36. The coil portions 38a, 38b may comprise separate sets of coil windings, in an embodiment. Each coil portion 38 may include loops that are wound in a respective plane that is parallel to the axis A of the membraneplate 36, in an embodiment (i.e., such that an axis of a loop of the coil is orthogonal to the axis A of the membraneplate 36). The coil portions 38a, 38b may be electrically coupled with each other in parallel or in series, in embodiments. The coil portions 38a, 38b may be mechanically coupled with the membraneplate 36 to move with the membraneplate 36.

FIG. 4 is an isometric view of the rotary flux transducer assembly 32 of FIG. 3, further including a pot 40. The pot 40 may be made completely or partially of soft iron, in an embodiment, and/or another material suitable for conducting magnetic flux (i.e., a material with good magnetic permeability) or, in an embodiment, a magnet such as a permanent magnet. The pot 40 may be configured in size, shape, and materials to conduct magnetic flux from one or more of the magnet portions 34a, 34b. In an embodiment, the pot 40 may include two or more portions 40a, 40b. One or more of the portions 40a, 40b may comprise a crescent shape. In an embodiment, the pot 40 may include two portions 40a, 40b, each comprising a crescent shape, placed on opposed radial sides of one or more magnet portions 34a, 34b.

The transducer 32 may include an air gap 42 between each lateral pot portion 40a, 40b and the magnet portions 34a, 34b; thus, two air gaps 42a, 42b are shown in FIG. 4. The first coil portion 38a may move through the first air gap 42a between the first pot portion 40a and the magnet portions 34a, 34b according to excursion of the membraneplate 36 (in a microphone embodiment) or to drive the membraneplate 36 (in a speaker embodiment). The gap through which the coil moves may be referred to herein as the “air gap” of a transducer.

Referring to FIGS. 3 and 4, the transducer assembly 32 may be scaled in size for a number of applications, as may the other rotary flux transducer embodiments that are illustrated and/or described in this disclosure. In an exemplary application, the transducer 32 may be designed for a membraneplate excursion of about 0.8 millimeters (mm). In such an embodiment, the transducer 32 may be designed and manufactured with about 0.5 mm (i.e., in the axial direction) between the membraneplate 36 and both the first magnet portion 34a and the second magnet portion 34b. Further, in such an embodiment, the transducer 32 may be designed and manufactured with an overall thickness in the axis A direction of about 3.5 mm. This accounts for the thickness of the membraneplate 36, the excursion amount plus clearance between the membraneplate 36 and each magnet portion 34a, 34b and an axial overlap, or field height, between each coil portion 38a, 38b and each of the magnet portions 34a, 34b while the membraneplate 36 is in a neutral position.

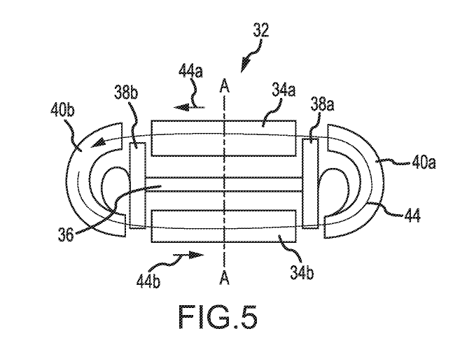

FIG. 5 is a cross-sectional view of the rotary flux acoustic transducer assembly portion 32 of FIG. 4, diagrammatically illustrating an exemplary embodiment of rotary propagation of magnetic flux. As illustrated in FIG. 5, in an embodiment, the magnet may include two portions 34a, 34b, and the two portions 34a, 34b may be polarized in opposite directions. For example, the a first magnet portion 34a may be polarized in a first polarity direction 44a, which first polarity direction 44a may be generally parallel with the membraneplate surface and generally perpendicular to the axis A of the membraneplate 36. The second magnet portion 34b may be polarized in a second polarity direction 44b, which second polarity direction 44b may be generally parallel with the membraneplate surface and generally perpendicular to the axis A of the membraneplate 36. The first polarity direction 44a may be opposite the second polarity direction 44b, in an embodiment.

One or more pot portions 40a, 40b may be disposed so as to conduct magnetic flux from the first polarity direction 44a to the second polarity direction 44b, in an embodiment. To accomplish this, one or more of the pot portions 40a, 40b may have a crescent shape, as noted above. Alternatively, one or more of the pot portions 40a, 40b may have a bracket shape or another appropriate shape. Two pot portions 40a, 40b may be disposed on opposed ends of the magnet portions 34a, 34b, along the direction of polarity of both magnet portions 34a, 34b. The pot or pot portions 40a, 40b may be positioned so that an upper portion of one or more pot portions 40a, 40b is substantially axially parallel with the first magnet portion 34a, and so that a lower portion of the one or more pot portions 40a, 40b is substantially axially parallel with the second magnet portion 34b, such that the pot portion conducts magnetic flux from the polarity direction 44a of the first magnet portion 34a to the polarity direction 44b of the second magnet portion 34b.

According to the polarity of the magnet or magnets and the position and shape of the pot or pot portions, the magnetic flux in the transducer may propagate along a continuous rotary path 44, in an embodiment, as illustrated in FIG. 5. The rotary path 44 may go around the membraneplate 36, in an embodiment. The coil or coil portions 38a, 38b may be disposed so that the magnetic flux path is perpendicular to the windings (i.e., loops) of the coil portions 38a, 38b. For example, as noted above, the magnet portions 34a, 34b may be polarized transverse to the axis A of the membraneplate 36, and the respective planes of the loops of the coil portions 38a, 38b may be parallel to the axis A of the membraneplate 36.

It should be noted that the configurations of magnets (e.g., magnet portions 34a, 34b) in this disclosure are exemplary in nature only, and do not exhaustively represent every possible magnet configuration that may find use in a rotary flux transducer. Thus, embodiments illustrating multiple symmetrical magnets, for example, are not limiting except as explicitly set forth in the claims. In a most general sense, a rotary flux transducer may include one or more magnet portions and zero or more magnetic flux conductors, collectively arranged so as to propagate magnetic flux in a rotary fashion. Thus, in an alternate embodiment, rotary magnetic flux may be created entirely with magnets.

Various embodiments of rotary flux acoustic transducer assemblies are illustrated herein with various arrangement of magnets and magnetic flux-conducting pot portions. Such embodiments are exemplary in nature only. It should be understood that magnets and magnetic flux-conducting components may be disposed and arranged in a large number of configurations, including some not explicitly illustrated herein, to achieve a rotary flux path consistent with the embodiments described in this disclosure.

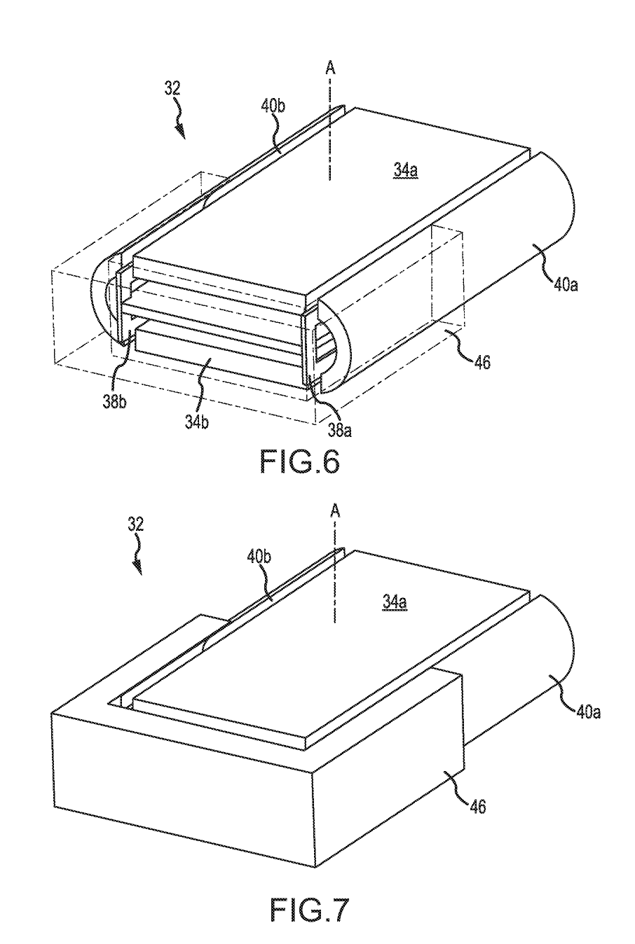

FIG. 6 is an isometric view of the rotary flux acoustic transducer assembly portion 32 of FIGS. 4 and 5, further including half of a housing 46, shown in phantom. FIG. 7 is an isometric view of the rotary flux acoustic transducer assembly 32 of FIG. 6, with the half housing 46 shown in opaque form. The housing 46 may be configured to retain the pot portions 40a, 40b, the magnet portions 34a, 34b, the membraneplate 36, and the coil portions 38a, 38b, in an embodiment. The housing 46 may be configured in size and shape to be directly coupled with the pot, in an embodiment. For example, the housing 46 may include one or more receiving formations for the one or more pot portions 38a, 38b. For example, in an embodiment in which the pot comprises two crescent-shaped portions 38a, 38b, the housing 46 may include crescent-shaped indentations configured to receive the pot portions 38a, 38b. The housing 46 may be coupled with the pot portions 38a, 38b with adhesive, in an embodiment. As noted above, only half of the housing 46 is illustrated; the housing 46 may be disposed around the entire radial circumference of the assembly 32, in an embodiment. The housing 46 may comprise plastic or another appropriate material, in an embodiment.

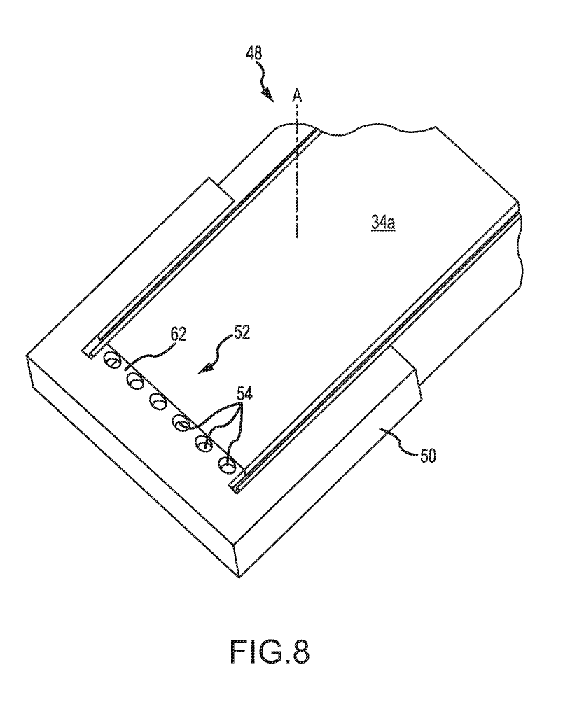

FIG. 8 is an isometric view of a portion of an embodiment of a rotary flux acoustic transducer assembly 48, illustrating half of a second embodiment of a housing 50. The assembly 48 may be substantially the same as the transducer assembly 32 as shown in FIG. 7 except as noted otherwise. Accordingly, the features noted above with respect to the first housing embodiment 46 may be included in the second housing embodiment 50. In addition, the housing 50 may include an air port 52 for the entry and exit of air. In FIG. 8, the housing 50 includes an air port 52 disposed in the top (which may be the “front” of the transducer assembly 48 when included in a device, such as a mobile phone) of the housing 50. Such an arrangement may be called a “front-firing transducer.” Similarly, one or more air ports (hidden from view in FIG. 8) may be provided in the bottom (which may be the “back” of the transducer assembly 48) of the housing 50. The bottom air ports may vent air into a backvolume that may be functionally similar to the second housing portion 12b illustrated in FIG. 2. Thus, air may enter and exit the housing 50 through one or more ports 52 that are arranged to be generally parallel with the axis A of the membraneplate. Air “above” the membraneplate may enter and exit the housing 50 through one or more air ports 52 in the top of the housing (such as those illustrated in FIG. 8), and air “below” the membraneplate may enter and exit the housing 50 through one or more air ports 52 in the bottom of the housing. Thus, the housing 50 may be configured, along with the membraneplate, to isolate the air below the membraneplate which may flow into a backvolume, from the air above the membraneplate that flows out of the housing. An air port 52 may comprise one or more holes. In an embodiment, an air port 52 may include a plurality of holes 54 in the housing 50, as illustrated in FIG. 8 (not all holes 54 are designated in FIG. 8).

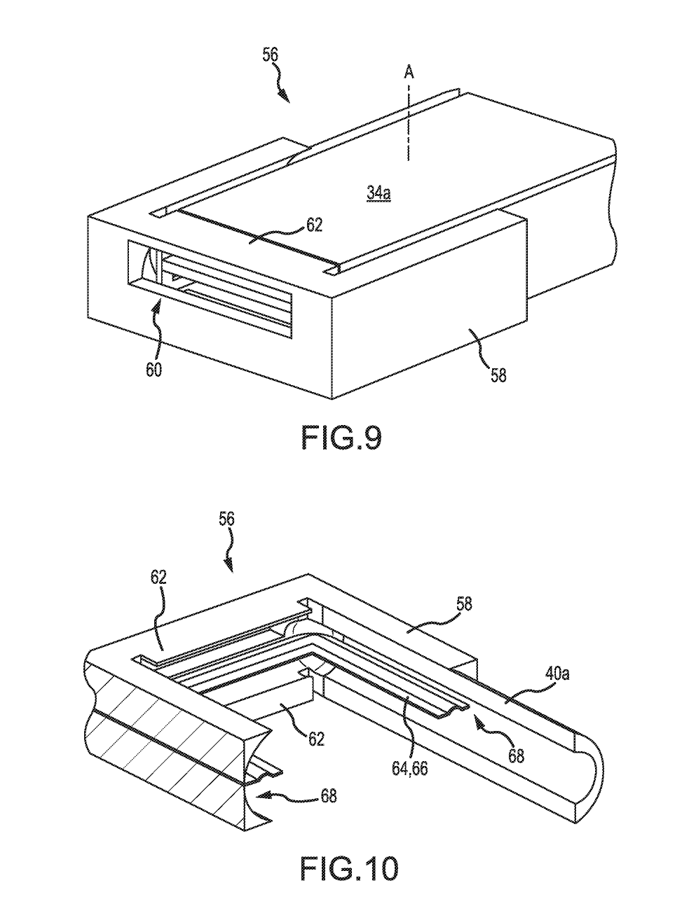

FIG. 9 is an isometric view of a portion of an embodiment of a rotary flux acoustic transducer assembly 56, illustrating half of a third embodiment of a housing 58. The assembly 56 may be substantially the same as the transducer assembly 32 as shown in FIG. 7 except as noted otherwise. Accordingly, the features noted above with respect to the first housing embodiment 46 may be included in the third housing embodiment 58. The housing 58 may include an air port 60 for the entry and exit of air. In FIG. 9, the housing 58 includes an air port 60 disposed in the “side” of the housing 58. The housing 58 may further include another air port (hidden from view in FIG. 9) disposed on the opposite side of the housing 50. Thus, air from “above” the membrane may enter and exit the housing 58 through a first one or more ports 60 that are arranged to be generally perpendicular with the axis A of the membraneplate, such as the air port 60 shown in FIG. 9, and air from “below” the membrane may enter and exit the housing 58 through a second one or more air ports 60 that are arranged to be generally perpendicular with the axis A, such as the above-described air port that is hidden from view in FIG. 9. Such an arrangement may be called a “side-firing transducer.”

Referring to FIGS. 8 and 9, the housing 50, 58 may further include a projection 62 or other formation configured to be directly coupled to a magnet portion. The housing 50, 58 may include projections 62 for coupling with one or more portions of multiple magnet portions, in an embodiment. Accordingly, in an embodiment in which the magnet comprises two magnet portions 34a, 34b (see FIG. 5, for example), the housing 50, 58 may include four projections 62, each coupled directly with a respective surface of a magnet portion 34a, 34b. A single projection 62 is shown in both FIG. 8 and FIG. 9. The housing 50, 58 (e.g., the projections 62 of the housing 50, 58) may be coupled with the magnet portions 34a, 34b with adhesive, in an embodiment.

FIG. 10 is a partial cross-sectional view of a portion of the transducer assembly 56 of FIG. 9, illustrating an exemplary arrangement for suspending the membraneplate 36 (much of the membraneplate 36 is omitted for clarity of illustration, the second pot portion 40b is omitted for clarity of illustration, and a portion of the housing 58 is in cross-section for clarity of illustration). A membrane 64 may include the membraneplate 36 and a suspension 66. The suspension 66 in a fully-suspended membraneplate arrangement also may separate the air volume located above the membraneplate from the air volume below the membraneplate, thus enabling acoustic emission due to the movement of the membraneplate.

In an embodiment, and as illustrated in FIG. 10, both the pot portions 40a, 40b and the housing 58 may include slots 68 configured to receive an edge of the membrane 64 (e.g., the suspension 66), so that the membrane 64 is directly mechanically coupled with one or more pot portions 40a, 40b and/or the housing 58. The respective slots 68 in the pot portions 40a, 40b may be arranged at the same axial position as the slot 68 in the housing 58, in an embodiment, such that the slot 68 in the pot portion 40a, 40b lines up with the slot 68 in the housing 58, and the membraneplate 36 (e.g., the suspension 66) may extend through the slot 68 in the pot portion 40a, 40b into the slot 68 in the housing 58. The slot 68 in each pot portion 40a, 40b may extend entirely through the thickness of the pot portion 40a, 40b, in an embodiment. The slot 68 in each pot portion 40a, 40b may extend along less than the entire length of the pot portion 40a, 40b (i.e., such that the pot portion 40a, 40b may be made of a continuous piece of material), in an embodiment, or may extend along the entire length of the pot portion 40a, 40b (i.e., effectively dividing the pot portion 40a, 40b into an upper half and a separate lower half), in an embodiment. The slots 68 in the housing 58 may extend through only a portion of the thickness of the housing 58, in an embodiment. The slots 68 in the housing 58 may extend along less than the entire length of the housing 58 (i.e., such that the housing 58 or a portion of the housing 58 may be made of a continuous piece of material), in an embodiment, or may extend along the entire length of the housing 58 (i.e., effectively dividing the housing 58 into an upper half and a separate lower half), in an embodiment. The membraneplate 36 (e.g., the suspension 66) may be coupled with the pot portions 40a, 40b and/or the housing 58 with adhesive, in an embodiment.

The rotary flux transducer embodiments of FIGS. 3-10 generally include a fully suspended membraneplate 36 having two coil portions 38a, 38b on opposed sides of the membraneplate 36. Numerous alterations and other configurations are possible and contemplated. For example, a single coil may be provided, rather than two coils, or more than two coils may be provided. In a further example, instead of a fully suspended membraneplate, a cantilevered membraneplate may be provided. FIGS. 11-17 illustrate various embodiments and features of a rotary flux transducer having a cantilevered membraneplate.

Reed-Type Rotary Flux Transducer.

FIG. 11 is an isometric view of a portion of an embodiment of a rotary flux acoustic transducer assembly 70. FIG. 12 is an isometric view of a portion of the transducer embodiment 70 of FIG. 11, further including a pot 72. The embodiment 70 of FIGS. 11 and 12 and similar embodiments may be referred to herein as a “reed-type” or “reed-style” rotary flux transducer, or more simply as a reed-type transducer or reed-style transducer. The reed-type transducer 70 may include a magnet 74, a membraneplate 76, a coil 78, and a pot 72.

The magnet 74 may include two or more magnet portions 74a, 74b, in an embodiment. As noted above, in an alternate embodiment, a single magnet may be used. The magnet may include a first portion 74a and a second portion 74b, with the first portion 74a and the second portion 74b disposed on opposite radial sides of the membraneplate 76. One or both of the magnet portions 74a, 74b may have transverse cross-sectional dimensions that are the same as or similar to each other, in an embodiment, and that are the same as or similar to the membraneplate 76, in an embodiment. The magnet portions 74a, 74b may additionally have the same or similar respective axial thicknesses, in an embodiment.

In contrast with the transducer embodiments illustrated in and/or described with respect to FIGS. 3-9, the magnet portions 74a, 74b of the reed-type transducer 70 may be disposed in a non-parallel configuration. The magnet portions 74a, 74b may be polarized substantially perpendicular to the axis A of the membraneplate 76, in an embodiment. The magnet portions 74a, 74b may be polarized in opposite directions, in an embodiment. The amount of space between the magnet portions may vary along the directions of polarization of the magnet portions 74a, 74b, in an embodiment. Similarly, in an embodiment, the distance between the membraneplate 76 (in a neutral position) and each of the magnet portions 74a, 74b may vary along the polarization directions of the magnet portions 74a, 74b.

The pot 72 may be functionally similar to the pots in the transducer embodiments of FIGS. 3-9. That is, the pot 72 may include multiple portions, in an embodiment, which portions may be disposed so as to conduct magnetic flux from the polarity direction of one magnet portion 74a to the polarity direction of another magnet portion 74b. The pot 72 may include two crescent-shaped portions 72a, 72b, in an embodiment, disposed on opposite ends of the magnet portions 74a, 74b. Accordingly, magnetic flux may propagate in a rotary path, substantially similarly to the manner illustrated in FIG. 5.

With continued reference to FIGS. 11 and 12, the coil 78 may include a single coil portion, in an embodiment, disposed on a first end 80 of the membraneplate 76. The coil 78 may be wound in a plane that is perpendicular to the polarity direction of one or more magnet portions 74a, 74b, in an embodiment.

A second end 82 of the membraneplate 76 that is opposite the end 80 to which the coil is coupled may be coupled with (e.g., fixed to) the portion 72b of pot 72 or some other structure. Accordingly, the membraneplate 76 may be configured to pivot about a rotational axis B and may act as a reed as in many musical instruments. In other words, the membraneplate 76 may be cantilevered, and/or may be or may form a part of a cantilevered assembly.

The second end 82 of the membraneplate 76 may be fixed according to one or more of several mechanical coupling configurations. For example, in a first possible configuration, the second end 82 of the membraneplate 76 may be clamped, such as between two segments of the portion 72b of pot 72, for example. In such an embodiment, excursion of the first end 80 of the membraneplate 76 may be as a result of bending of the membraneplate. Alternatively, in a second possible configuration, the second end 82 of the membraneplate 76 may be coupled to the portion 72b of pot 72 or other structure with a suspension. Still further, such a suspension may be coupled with each non-fixed edge of the membraneplate. For example, a first edge of a rectangular membraneplate may be fixed, and the other three edges may be coupled with a suspension, in an embodiment. Such a suspension may be functionally similar to the suspension 22 in FIG. 1 or suspension 66 in FIG. 10, for example. In such an embodiment, excursion of the entire membraneplate 76 may be as a result of movement permitted by the suspension. In contrast with a fixation of an edge of the membraneplate, which fixation may result in a rotational axis for excursion of the membraneplate, a suspension of an edge of the membraneplate may permit excursion of the suspended edge sufficient to operate the membraneplate for electroacoustic transduction.

The coupling between the membraneplate 76 and the portion 72b of pot 72 or other structure may determine the performance characteristics of the transducer. For example, if the membraneplate 76 is clamped, the resonance frequency of the transducer may be defined by the stiffness of the membraneplate, which may result in a high Q factor for the transducer's mechanical system. In contrast, if the membraneplate 76 is suspended, rather than clamped, the membraneplate 76 may perform comparably to a standard transducer. It should be understood that the description herein of “reed-style” implementations may encompass a clamped membraneplate, a suspended membraneplate, and/or a membraneplate that is mechanically coupled with the portion 72b of pot 72 or other structure in some other way.

The transducer 70 may include an air gap 84 between the first pot portion 72a and the magnet portions 74a, 74b. Like the rotary flux transducer embodiments of FIGS. 3-9, the coil 78 may move through the air gap 84 according to excursion of the membraneplate 36 (in a microphone embodiment) or to drive the membraneplate 36 (in a speaker embodiment).

In a speaker embodiment, the reed-style transducer 70 may not move as much air as a traditional speaker (or a rotary flux transducer according to one of the embodiments of FIGS. 3-9) having the same-size membraneplate. This potential disadvantage may be offset, though, by only using a single coil 78 in the reed-style transducer 70, resulting in easier manufacturing and in less space needed for air gaps (consequently allowing for higher magnetic flux within the same space). Another potential advantage of the reed-style transducer 70, which results from the membraneplate 76 being cantilevered (that is, fixed at one edge) is increased reliability and reduced tumbling behavior of moving parts due to reduced degrees of freedom. Furthermore, the fixed edge allows the coil 78 to be electrically coupled with separate wiring at or near the rotation axis B, where strain on the separate wiring is minimal, eliminating wireloops attached to the coil and reducing the chance of wiring failure that is a common problem in traditional transducers. Electrical pathways may be provided on the membraneplate (via printed circuits, conduits or by simply securing wires) from the location where the coil or coils are disposed to near or at the fixed edge, where an electrical connection out of the transducer assembly can be made. With a less stressful external electrical connection, and the elimination of wireloops, it is easier to provide multiple electrical connections (i.e., more than the two required for a single coil) to the transducer assembly. The additional electrical connections allow for reliable connections to multiple coils, for example, or for one or more integrated circuits disposed on, or on an edge of, the membraneplate, such circuits being, for example, amplifiers, buffers, analog-to-digital converters, etc.

The reed-style transducer 70 also may differ from a traditional transducer assembly in the structure that may be provided for mechanical damping. For example, in a speaker including a traditional transducer assembly having a single suspension, mechanical damping is generally achieved by the entire suspension. Accordingly, design for the entire suspension of a traditional transducer assembly may account for mechanical damping as well as acoustic characteristics. In contrast, for a reed-style transducer assembly, the fixation between the fixed edge of the membraneplate and the remainder of the assembly may provide a high degree of mechanical damping, in an embodiment, allowing any additional suspension on the remaining sides of the membraneplate to be highly elastic.

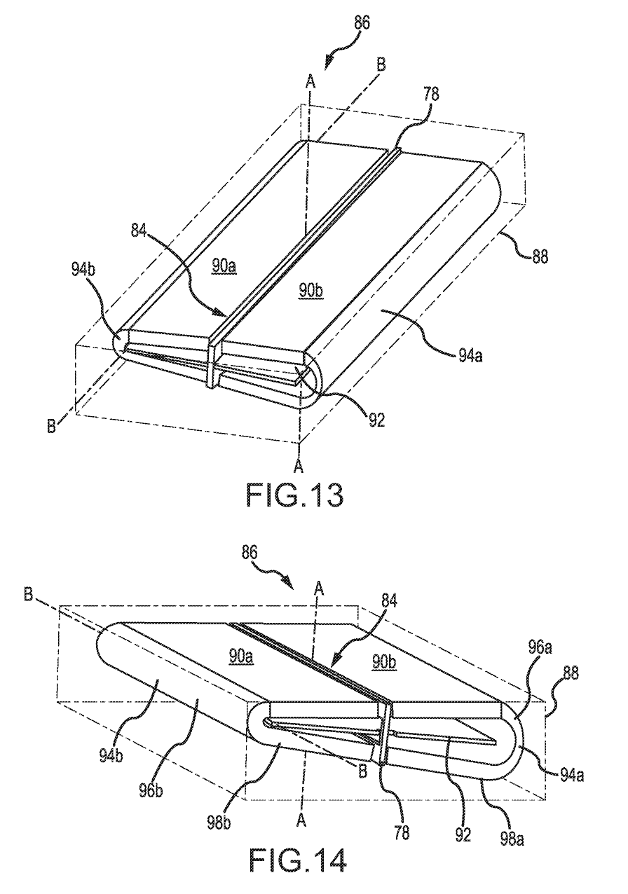

FIGS. 13 and 14 are isometric views of a second embodiment of a reed-style rotary flux acoustic transducer assembly 86, with a housing 88 shown in phantom. The second reed-style transducer 86 may be substantially the same as the first reed-style transducer 70, except as otherwise described below. The transducer 86 may include a housing 88, two magnet portions 90a, 90b, a membraneplate 92, a coil 78, and two pot portions 94a, 94b.

The first and second magnet segments 90a, 90b may be polarized in the same direction (e.g., a direction that is nearly parallel with the surface of the membraneplate 92 and nearly perpendicular to the axis A of the membraneplate 92) and disposed on the same side of the membraneplate 92 as each other so as to create a rotary flux path in conjunction with the pot portions 94a, 94b.

The pot segments 94a, 94b may include respective crescent portions 96a, 96b and respective planar portions 98a, 98b to create a rotary flux path in conjunction with the magnet portions 90a, 90b.

The second reed-style rotary flux transducer 86 may include a coil 78 coupled with a middle portion of the membraneplate 92, rather than with an end portion of the membraneplate as in previous embodiments in this disclosure. Of course, the coil 78 may be provided at any distance from the rotational axis B of the membraneplate 92. Accordingly, the air gap 84 may be provided between the first magnet portion 90a and the second magnet portion 90b, and may be further provided between the first pot portion 94a and the second pot portion 94b.

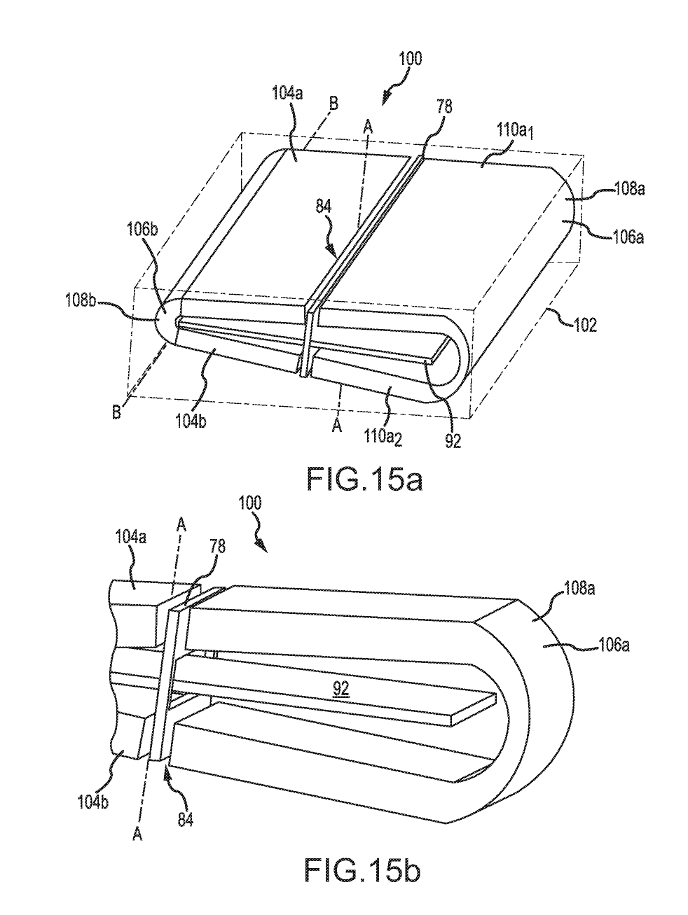

FIGS. 15a and 15b are isometric views of a portion of a third reed-style embodiment of a rotary flux acoustic transducer assembly 100. A housing 102 is shown in phantom in FIG. 15a. The third reed-style rotary-flux transducer 100 may be substantially the same as the second reed-style transducer 86 (see FIGS. 13 and 14) except as otherwise described below.

Referring to FIGS. 15a and 15b, the third reed-style rotary-flux transducer 100 may include first and second magnet portions 104a, 104b that are polarized in opposite directions (e.g., which directions are nearly parallel to the surface of the membraneplate and nearly perpendicular to the axis A of the membraneplate). The third reed-style transducer 100 may further include first and second pot portions 106a, 106b positioned and shaped so as to conduct magnetic flux in a rotary path, along with the magnet portions 104a, 104b, around the membraneplate. The first and second pot portions may be or may include crescent-shaped portions 108a, 108b, in an embodiment. The first pot portion may further include two planar portions 110a₁, 110a₂ In the third reed-style rotary flux transducer 100, the air gap 84 may be provided between the first magnet portion 104a and the first pot portion 106a (e.g., a first planar portion 110a₁ of the first pot portion 106a), and may be further provided between the second magnet portion 104b and the first pot portion 106a (e.g., a second planar portion 110a₂ of the first pot portion 106a).

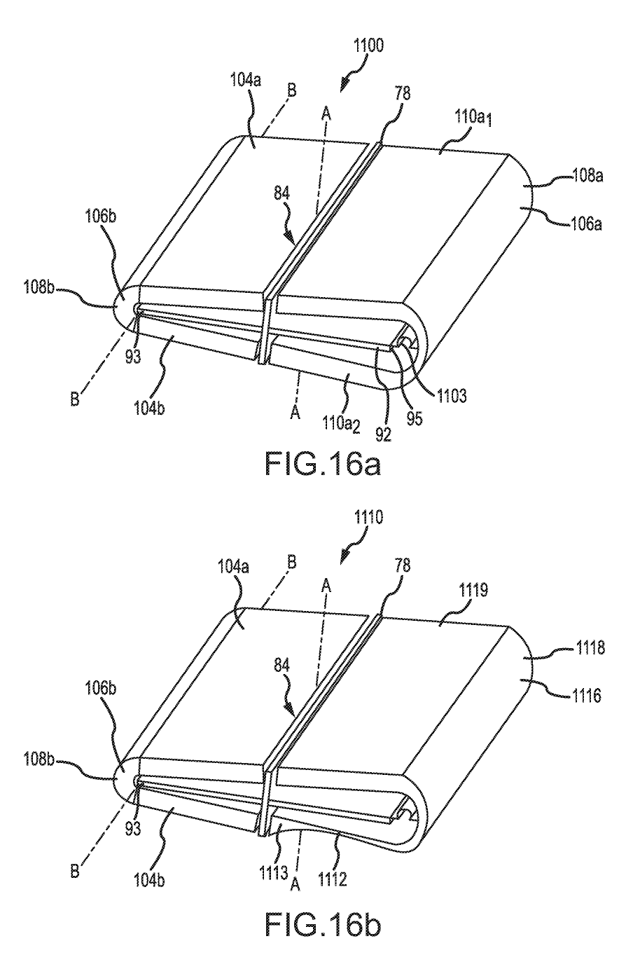

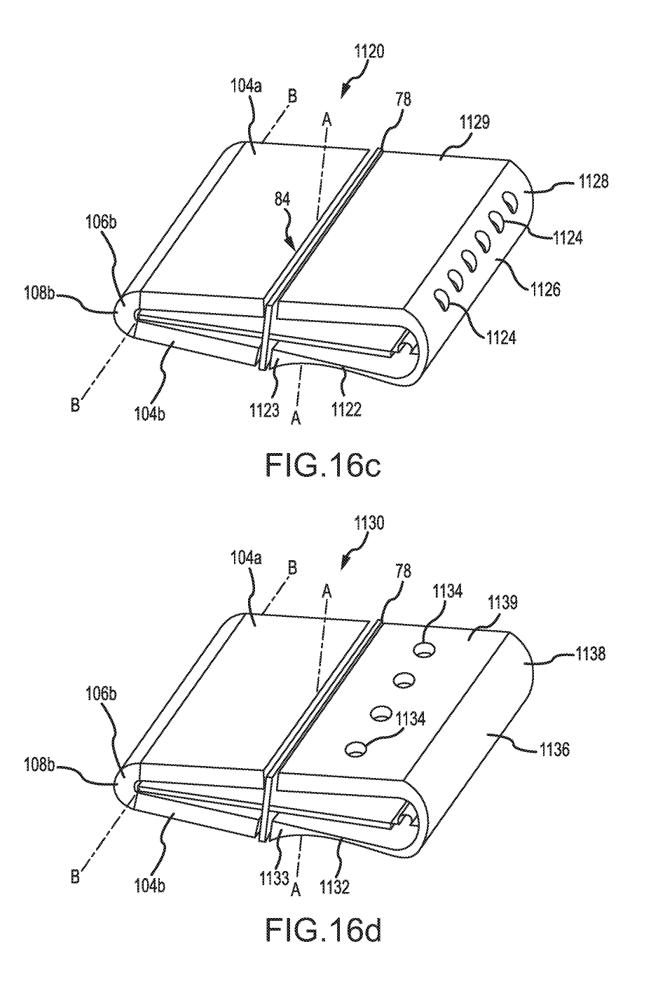

FIGS. 16a-16d are isometric views of portions of four further alternative embodiments of a reed-style rotary flux acoustic transducer assembly. The further alternative embodiments of FIGS. 16a-16d of the reed-style rotary-flux transducer may be substantially the same as the third reed-style transducer 100 (see FIGS. 15a and 15b) except as otherwise described below.

Referring to FIG. 16a, a further alternative embodiment of a reed-style rotary-flux transducer 1100 is shown. Rotary-flux transducer 1100 is substantially the same as the reed-style transducer 100. Just as with the reed-style transducers 70, 86 and 100, an end 93 of membraneplate 92 may be fixed and configured to pivot about the rotational axis B. The opposite end 95 of membraneplate 92 may be coupled to suspension member 1103 along its edge, with suspension member 1103 coupled to first pot portion 106a. The suspension member 1103 may be functionally similar to the suspension 22 in FIG. 1 or suspension 66 in FIG. 10, for example. In further embodiments, suspension member 1103 may extend around and be coupled to all non-fixed edges of membraneplate 92 (i.e., the radial edges between and perpendicular to ends 92, 95), such that membraneplate 92 if fixed on one edge and suspended on all other edges. In this configuration, the suspension member helps to separate the air volume above the membraneplate 92 from the air volume below the membraneplate.

Referring to FIG. 16b, another further alternative embodiment of a reed-style rotary-flux transducer 1110 is shown. Rotary-flux transducer 1110 is substantially the same as the reed-style transducer 1100. Reed-style transducer 1110 may further include first pot portion 1116, positioned and shaped, along with the first and second magnet portions 104a, 104b and second pot portion 106b, so as to conduct magnetic flux in a rotary path around the membraneplate 92. In this embodiment, first pot portion 1116 includes a planar portion 1112, opposite planar portion 1119, where the planar portion 1112 has a thickness in the direction of axis A that is substantially less than the thickness of planar portion 1119. First pot portion 1116 may also include a crescent-shaped portion 1118 having a thickness that transitions from the thickness of planar portion 1119, to the thickness of planar portion 1112. Planar portion 1112 may also include a transition end 1113, located adjacent to the air gap 84, where the thickness of the transition end 1113 smoothly transitions from the reduced thickness of the planar portion 1112 to substantially the same thickness of magnet portion 104b. The reduced thickness along at least a portion of planar portion 1112 helps to reduce the total height of transducer 1110. It should be understood that a reduction in thickness is not limited to only within the planar portion 1112.

Referring to FIGS. 16c and 16d, two further alternative embodiments of a reed-style rotary-flux transducer 1120, 1130 are shown. Both rotary-flux transducers 1120, 1130 are substantially the same as the reed-style rotary-flux transducer 1110 of FIG. 16b. Rotary-flux transducers 1120, 1130 may provide for improved air flow off the surfaces of the membraneplate 92. In the rotary flux transducers of FIGS. 3-16b, air enters and exits the spaces above and below the membraneplate (i.e., between the membraneplate and a magnet or pot portion, as the case may be) through the air gap in which the coil resides and/or through the exposed lateral sides transverse to the magnetic flux path. These air flow pathways may not be the most desirable, however. For example, air flow through the air gap results in the modulation of the acoustic-port impedance due to the moving coil in the air gap. Rotary-flux transducers 1120, 1130 provide air pathways that allow for a more efficient transfer of air from the membraneplate surfaces.

Rotary-flux transducer 1120 of FIG. 16c may contain one or more air ports 1124, located on a crescent-shaped portion 1128 of first pot portion 1126. Rotary-flux transducer 1130 of FIG. 16d may contain one or more air ports 1134 in a planar portion 1139 of first pot portion 1136. With either rotary-flux transducers 1120, 1130 further air ports could be located on a lower planer portion 1122, 1132, to allow air flow from the lower surface of membraneplate 92.

In further embodiments, substantially similar to rotary-flex transducer 1100 of FIG. 16a, air ports substantially similar to air ports 1124, 1134 may be included on one or both of first and second magnet portions 104a, 104b. In still further embodiments, air ports can be included on one or both magnet portions 104a, 104b and on one or more locations on pot portions 106a, 106b. Accordingly, it should be understood that air ports may be located on any portion of the rotary-flux structure comprised of a first magnet and at least a second magnet or a magnetic flux conductor.

In an embodiment of a rotary-flux transducer comprising a housing, such as in transducers 48, 56, 86 and 100 of FIGS. 8-10 and 13-15a, air ports 1124, 1134 may be configured to facilitate air flow from the surfaces of the membraneplate through air ports in the housing to the outside of the housing. Thus, placement of the air ports may be on any part of the rotary-flux structure to accommodate various transducer arrangements, such as front-firing and side-firing transducers, as described previously.

Reed-Style Rotary Flux Transducer—Sound Pressure Level.

A reed-style rotary flux transducer assembly is capable of improved performance over a similarly-sized traditional loudspeaker assembly in terms of sound pressure level. The standard method of calculating an estimate of the sound pressure level (a common metric of speaker performance) of a standard speaker with respect to another standard speaker is by simply comparing the respective forces applied by the respective coils to the respective membraneplates and the respective moved masses. Two basic equations are relevant to an estimation of sound pressure level, set forth as equations (1) and (2) below. First, the relationship between the force on the coil, the moved mass, and the acceleration of the moved mass is set forth in equation (1) below:

a=F/m (1)

where a is acceleration, F is the coil force (which is respectively the product of the magnetic flux density, the length of wire in the magnetic field, and the current through the coil), and m is the moved mass (treated as a point mass).

Second, the sound pressure value SPL is given by equation (2) below:

$$SPL = 20 log \frac{λ a {S}_{D}}{{P}_{0}} \qquad ( 2 )$$

where SPL is the sound pressure level with respect to P₀ (the reference sound pressure value of 20 μPa), λ is

$$\frac{{ρ}_{0}}{2 π}$$

(where ρ₀ is air density), S_{D} is the effective area of the membraneplate, and a is again acceleration. Thus, solving for a and S_{D} allows SPL to be determined.

In order to estimate the sound pressure level for the reed-style transducer, equations (1) and (2) need to be considered in the rotational domain, rather than the translational domain, due to the cantilevered movement of the membraneplate, rather than translational movement along the axis of the membraneplate (as in a traditional speaker). Accordingly, the rotational version of equation (1) is given by equation (3) below:

φ=M/J (3)

where φ is angular acceleration, M is moment of torque, and J is moment of inertia. To calculate the moment of inertia J, equation (4) below can generally be applied:

J=∫_{V}r²ρ(r)dV (4)

where r is the distance from the center of the mass and ρ is the density of material in volume V.

For the coil arrangement of FIGS. 13-15b (i.e., a coil disposed on the midpoint of a cantilevered membraneplate), equation (4) can be written in expanded form as equation (5) below:

$$J = 2 X {ρ}_{c} {fw}_{s} Y [ {d}_{y}^{2} + {( \frac{Z - \frac{{W}_{s}}{2}}{2} )}^{2} + \frac{YZ}{X} {d}_{y}^{2} ] + {XM}_{y} {M}_{z} {ρ}_{m} ( \frac{1}{3} {M}_{y}^{2} + \frac{1}{12} {M}_{z}^{2} ) \qquad ( 5 )$$

where the moment of torque M can be calculated according to equation (6) below:

M=d_{y}F (6)

and where aS_{D} (see equation (2)) can be calculated according to equation (7) below:

$${aS}_{D} = X {\int }_{0}^{{M}_{y}} r ϕ d r = \frac{{XM}_{y}^{2} ϕ}{2} \qquad ( 7 )$$

where wₛ is winding space, X is the length of the coil (i.e., in the longer dimension in the plane of a coil winding), Z is the height of the coil (i.e., in the shorter dimension in the plane of a coil winding), Y is the thickness of the coil (i.e., along the longitudinal axis around which the coil is wound), ρ_{c} is the density of the material used for the coil (which may be, for example only, a metal, such as copper), ρₘ is the density of the membraneplate, d_{y} is the distance of the coil from the hinge axis of the membraneplate, M_{y} is the width of the membraneplate (i.e., from the hinge axis to the opposite side of the membraneplate), and M_{z} is the thickness of the membraneplate. f is a spacefactor that accounts for the configuration coils being bonded wires, such that the entire cross-sectional area between the inner and outer diameter of the coil is not filled with coil material and thus weighs less than if this area was filled with coil material. f accounts for the loss of mass, and is generally between about 0.5 and 0.7.

A simplified examination confirms the plausibility of the above solution. If the translational formula is treated as a special case of the rotational formulas, the mass may be considered as separated from the axis by a (generally relatively large) distance r. The moment of torque is then r*F, the moment of inertia m*r², and the acceleration is given by equation (8) below:

$$\frac{a}{r} = \frac{rF}{{r}^{2} m} \qquad ( 8 )$$

which reduces to equation (1).

If the coil is treated as a point mass instead of as a coil and the mass of the membraneplate is ignored, then the angular acceleration φ may be calculated according to equation (9) below:

$$ϕ = \frac{{d}_{y} F}{{d}_{y}^{2} m} \qquad ( 9 )$$

Combining equations (7) and (9) yields equation (10) below:

$${aS}_{D} = \frac{XF}{{d}_{y} m} {\int }_{0}^{{M}_{y}} r d r = \frac{{XM}_{y} F}{m} \qquad ( 10 )$$

The effective area is XM_{y}, which results in the same SPL as a standard electroacoustic transducer design (i.e., the design of FIG. 1) for a given coil length X.

Relative to a standard electroacoustic transducer design, the reed-style rotary flux transducer only moves half as much air as a traditional transducer assembly given an equivalent maximum excursion (i.e., where the maximum excursion of the free end of the reed-style membraneplate is equal to the maximum excursion of the membraneplate of a traditional transducer). As a result, less space may be needed for backvolume, and space under the transducer (for example, space within the housing under the pot or magnet, such as under magnet portion 104b in FIG. 15a) can be used as backvolume. When comparing the performance and design advantages of a standard electroacoustic transducer design and the reed-style rotary flux transducer, the necessary backvolume may be taken into account. Thus, when comparing a known design, such as the design illustrated in FIG. 2, to a reed-style rotary flux design as found in FIG. 13, advantages for the rotary flux reed-style design can be seen. The dimensions of the housing 88 in FIG. 13 may be equal to the dimensions of the housing in FIG. 2, as may be the volume of the backvolume, yet more space within the housing 88 of the reed-style rotary flux design may be dedicated to magnetic material. On the other hand, equation (10) neglects the moved mass of the membraneplate, resulting in reduced performance of the reed-style transducer relative to equation (10). All told, relative to a standard electroacoustic design, a reed-style rotary flux transducer having a coil disposed on the midpoint of the membraneplate (as illustrated in FIGS. 13 and 14) may provide a performance increase of about 2-3 dB based on the stronger magnetic field resulting from the geometric configuration of the embodiment. Simulations confirm this improvement.

The calculation of equation (10) is based on a coil positioned at the midpoint of the membraneplate (i.e., halfway between the hinge axis and the opposing end of the membraneplate). If the coil is instead moved to a third of the distance between the hinge axis and the opposite end of the membraneplate (i.e., with a third of the membraneplate width between the coil and the hinge axis and two thirds of the membraneplate between the coil and the side of the membraneplate that opposes the hinge axis), the calculation of equation (10) changes to equation (11) below:

$${aS}_{D} = \frac{XF}{{d}_{y} m} {\int }_{0}^{{M}_{y}} r d r = \frac{3 {XM}_{y} F}{2 m} \qquad ( 11 )$$

which is a further theoretical performance increase, which increase is lessened by the limitation of the membraneplate acting as a mechanical lever.

The performance increase achieved by moving the coil closer to the hinge axis is a result of reducing the mass impact due to the vicinity to the rotary axis. Another limitation on the performance increase of moving the coil closer to the hinge axis is a consequent shift in resonance frequency. To have a true calculation of transducer performance, resonance frequency should be taken into account, which can be accomplished by increasing the value used for the mass of the coil, thereby increasing the BL value. This increases the air gap as well, but the magnet setup is completely different from the standard speaker, which can be seen from equations (12) and (13) below.

The solenoidal nature of magnetic flux in combination with the Laplace law leads to equations (12) and (13):

AₘBₘ−A_{g}B_{g}=0 (12)

Hₘlₘ−H_{g}l_{g}=0 (13)

where Aₘ is the area of the magnet perpendicular to the magnetic flux, Bₘ is the magnetic flux in the magnet, A_{g} is the area of the air gap perpendicular to the magnetic flux, B_{g} is the magnetic flux in the air gap, Hₘ is the magnetic field strength of the magnet, lₘ is the length of the magnet in the direction of flux propagation, H_{g} is the magnetic field strength in the air gap, and l_{g} is the length of the air gap perpendicular to the magnetic flux. Equations (12) and (13) may be used to determine the operating point of the transducer.

The operating point of a standard electroacoustic transducer is given by the ratio of Bₘ to Hₘ, given in equation (14) below:

$$\frac{{B}_{m}}{{H}_{m}} = - {μ}_{0} \frac{{A}_{g} {l}_{m}}{{A}_{m} {l}_{g}} \qquad ( 14 )$$

For a standard electroacoustic transducer, lₘ is equal to l_{g} and the ratio of A_{g} to Aₘ is in the range of 0.25, resulting in an operating point ratio of about 0.25. Increasing the air gap therefore reduces the value further on shifting the operation point to higher negative magnetic field strengths.

The rotary flux speaker achieves quite different results. In a rotary flux transducer according to the present disclosure, lₘ may be about five times larger than l_{g}, and A_{g} may equal Aₘ, resulting in an operating point ratio of about 5. Increasing the air gap therefore reduces the operating point value, as well, but without as great an impact as in a standard transducer. In addition, the operating point is closer to the magnetic axes and therefore not prone to thermal demagnetization.

Multi-Coil Rotary Flux Transducer.

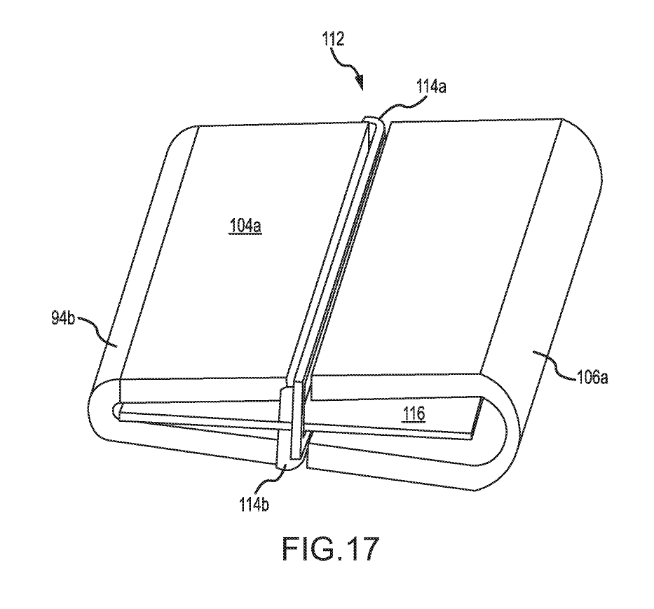

FIG. 17 is an isometric view of a portion of an embodiment of a rotary flux acoustic transducer assembly 112 having two coils 114a, 114b a single magnet portion 104a, a membraneplate 116 and two pot portions 106a, 94b. The two-coil transducer assembly 112 may include a first coil 114a and a second coil 114b, in an embodiment. The two coil assembly illustrated in FIG. 17 is substantially the same as the second reed-style transducer assembly 100 except as otherwise described. It should be understood, however, that a multiple-coil assembly may be used in conjunction with any rotary flux transducer assembly illustrated and/or described herein, or with variants of such embodiments. The benefits and advantages of a multiple-coil transducer assembly are described in Int'l Pat. Publ. WO2014/175724, the disclosure of which is incorporated herein as if set forth in its entirety.

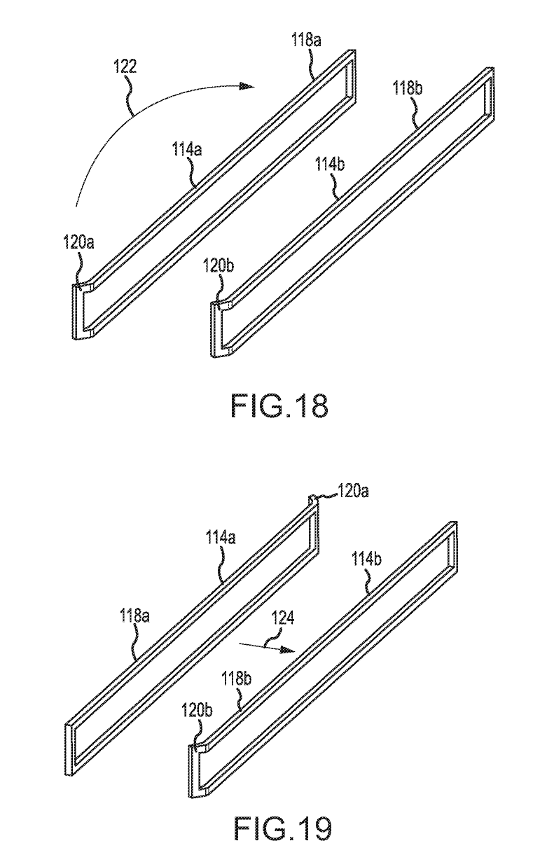

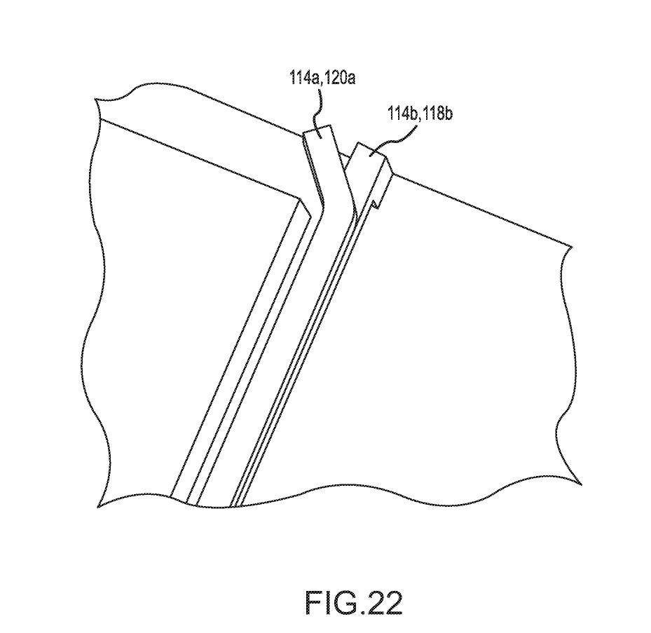

FIGS. 18-22 are isometric views of the rotary flux acoustic transducer assembly 112 of FIG. 17 at various stages of assembly. As shown in FIG. 18, in a first stage of assembly, the two coils 114a, 114b may be wound separately. Each coil may have a generally planar portion 118a, 118b. At one end, in an embodiment, each coil may have a generally off-plane portion 120a, 120b. The off-plane portion 120a, 120b may be angled off from the planar portion, in an embodiment (i.e., the plane in which a loop portion in the off-plane portion 120a, 120b is disposed may be at a nonzero angle with the plane in which a loop portion in the plane portion 118a, 118b is disposed).

The off-plane portion 120a, 120b may be provided so as to place the planar portions 118a, 118b of two coils in substantially the same plane by flipping one of the coils, as indicated by the arrow 122 in FIG. 18. In a second stage of assembly, shown in FIG. 19, the two coils 114a, 114b may be placed together (as indicated by the arrow 122) so that the planar portions 118a, 118b of the two coils 114a, 114b are in substantially the same plane.

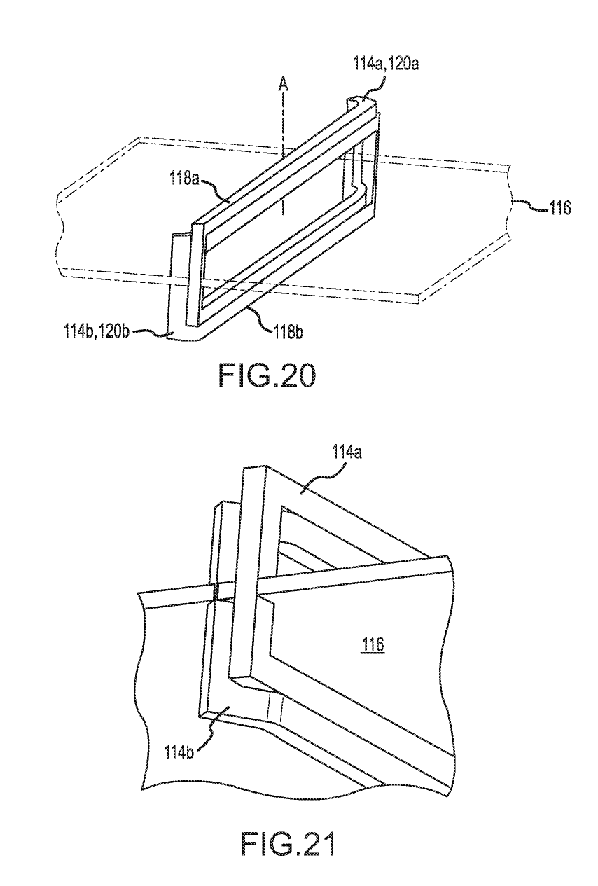

As shown in FIGS. 20-22, the joined coils 114a, 114b may then be placed around a selected portion of the membraneplate 116 (shown in phantom in FIG. 20). The coils 114a, 114b may be joined so that the loops of one coil 114a are “above” the loops of the other coil 114b (i.e., along the axis A of the membraneplate). In this arrangement, the loops of coil 114b are closer to the surface of the membraneplate 116 on the upper side, while the loops of coil 114a are closer to the surface of the membraneplate 116 on the lower side. The coils 114a, 114b are thus arranged asymmetrically within the path of magnetic flux in the transducer. The coils 114a, 114b may be coupled with an end of the membraneplate 116, or with a middle portion of the membraneplate 116, in embodiments. The coils 114a, 114b may be disposed on the membraneplate 116 so that the planar portions 118a, 118b of the coils 114a, 114b are perpendicular to the path of magnetic flux in the transducer.

A rotary flux transducer as illustrated and described herein may provide numerous advantages over known acoustic transducer designs. First, the number of parts in the rotary flux transducer is less than in a traditional transducer, resulting in easier assembly and manufacturing. Second, a greater volume of magnetic material may be provided in a rotary-flux transducer than in an equivalently-sized known transducer, increasing the sensitivity and output of the transducer. Third, cuboid magnet portions may be used, which are generally inexpensive, helping offset the cost of the relatively larger magnet. Fourth, both side ports and/or front ports for air flow may be accommodated. Fifth, the coil can be wound directly on the membraneplate, rather than requiring a separate bobbin, in embodiments. Sixth, the space available for the coil is more easily alterable than in a traditional transducer design, thereby allowing for different placements of the coil and/or different sizes of the coil, as desired. Seventh, wireloops are not required to be attached to the coil since the coil may be electrically connected to separate wiring at or near the rotation axis B, where the strain on the separate wiring will be minimal.

Furthermore, a double-coil embodiment may offer further advantages. First, the double coil embodiment may be simpler to combine with a class D amplifier due to its four-channel connection. Second, the double coil may be formed from two identical coils that eliminate the need for a bobbin.

Integrated Amplifier.

Any of the rotary flux transducer embodiments illustrated and/or described herein may be supplemented with an amplifier on the membraneplate. For example, in an embodiment, an amplifier may be printed on the membraneplate as a flex circuit. Still further, in an embodiment, the amplifier may be a class D amplifier.

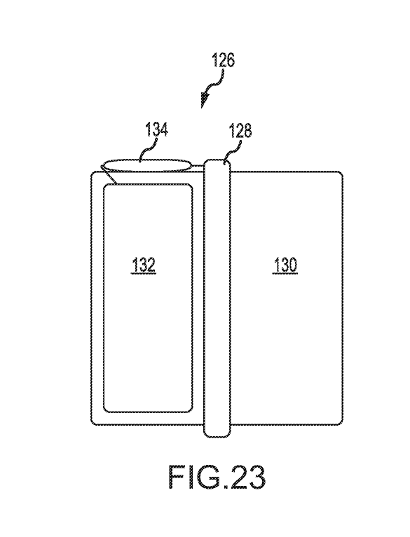

FIG. 23 is a diagrammatic view of an assembly 126 that may find use in a rotary flux transducer. The assembly may include a coil 128, a membraneplate 130, an amplifier 132, and an electrical output damping circuit portion 134. The membraneplate 130 and coil 128 may be or may include one or more membraneplates and coils of this disclosure. The amplifier 132 may be a class D amplifier, in an embodiment, and may be printed on the membraneplate 130. For example, the amplifier 132 may be printed on a surface of the membraneplate 130.

The electrical output damping portion 134 may be provided electrically between the amplifier 132 and the coil 128, in an embodiment. That is, the electrical output damping portion 134 may receive the output signal of the amplifier 132 and output a damped version of that signal for input to the coil 128 (i.e., in an embodiment in which the assembly 126 forms part of a speaker). The electrical output damping portion 134 may be or may include, for example only, ferrite beads and/or another electrical damping component. The electrical output damping portion 134 may be disposed on or coupled with an edge of the membraneplate 130.

In an alternative embodiment, damping portion 134 is omitted in the arrangement and shielding of the amplifier 132 may be provided by using the rotary flux structure, comprised of one or more magnet portions and one or more pot portions as described in any of the embodiments above, for grounding. In such an embodiment, the additional cost of the damping circuit is avoided.

An amplifier integrated with a rotary flux transducer assembly, and a reed-style rotary flux transducer assembly in particular, may outperform known amplifier-on-membrane arrangements. For example, due to the fixation of an edge of the membrane, wiring for the amplifier may be simplified and less prone to failure than in known arrangements. Furthermore, an amplifier integrated on a reed-style membraneplate may present a lower input impedance than a known amplifier-on-membrane arrangement because the impedance of the connection between the amplifier and the transducer is minimized. For example, if an amplifier can drive a 4 ohm (Ω) speaker impedance, the contact impedance (in the range of tenths of an ohm, in embodiments) lowers the efficiency by the ratio of overall impedance to speaker impedance. If the same contact/connection impedance is added to a speaker impedance of 2Ω, for example, the efficiency is reduced even further. Thus, reducing the connection impedance becomes increasingly significant as the impedance of the speaker itself drops.

The benefits described herein for an amplifier circuit disposed on, or on an edge of, the membraneplate are also applicable to other electrical circuits, i.e., integrated circuits, that may be disposed on, or on an edge of, the membraneplate. Examples of other circuits, in additional to amplifiers, include buffers, analog to digital converters, and other circuits useful in acoustic transducer applications. The reed-style rotary flux transducer in particular may facilitate the inclusion of multiple electrical circuits on the membraneplate due to the reduction in stress on the electrical connections in such an arrangement.

Membraneplate for Reed-Style Transducer.

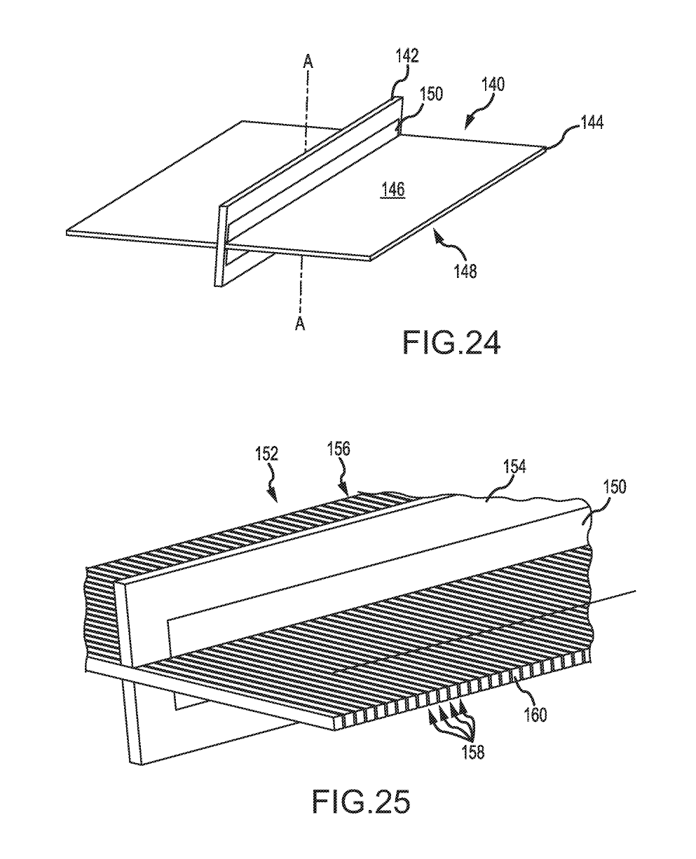

A reed-style rotary flux transducer assembly may present different stresses on the membraneplate than a membraneplate suspended in a traditional manner. Accordingly, a membraneplate for a reed-style transducer may differ from a membraneplate for a fully-suspended membrane. For reference, a membraneplate constructed for a rotary flux implementation according to traditional multi-layer membrane design principles will first be described. FIG. 24 is an isometric view of a membraneplate 140 having a multi-layer construction, similar to known membraneplate constructions, coupled with a mid-membrane coil 142 for a rotary flux transducer implementation.

The membraneplate 140 may include a core layer 144 and two outer layers 146, 148 on opposite sides of the membraneplate, in an embodiment. The three layers 144, 146, 148 may be arranged along the central axis A of the membraneplate 140. The central layer 144 may include a foam matrix, in an embodiment. One or both of the outer layers 146, 148 may include a laminated metal, in an embodiment. For example, one or both of the outer layers 146, 148 may include laminated aluminum. The membraneplate 140 may be symmetric along the central axis A; that is, the two outer layers 146, 148 may be the same in materials and dimensions, in an embodiment. The outer layers 146, 148 may each have a thickness of about ten (10) micrometers (μm), in an embodiment. The core layer 144 may have a thickness of about two hundred (200) μm, in an embodiment. Of course, other thicknesses are possible and contemplated for different embodiments.

The coil 142 may be disposed on a bobbin 150, in an embodiment, on which the coil 142 is wound. The bobbin 150 may be included in the finished transducer assembly and may provide structural support to the membraneplate 140. Though not necessarily illustrated in every embodiment, the coil of any transducer embodiment of this disclosure may be provided on a bobbin.

The membraneplate 140 of FIG. 24, due to its uniformity along its width and length, may be appropriate for a transducer assembly in which it is suspended on all sides, or symmetrically suspended along two sides or otherwise on multiple sides. In an embodiment, it may be adequate for a reed-style embodiment, as well. But the membraneplate 140 may not be ideal for a reed-style embodiment due to the distribution of force along one axis that accompanies excursion of the reed-style membraneplate, rather than a circumferential distribution of force as in fully-suspended membraneplates. Accordingly, a membraneplate configured for use in a reed-style rotary flux transducer assembly may include features tailored for the stress distribution of cantilevered excursion.

FIG. 25 is an isometric view of an exemplary embodiment of an assembly including a membraneplate 152 and a coil 154 that may find use in a rotary flux transducer, such as a reed-style rotary flux transducer. The membraneplate 152 may comprise a core layer 156 and may further comprise outer layers, though the outer layers are omitted from FIG. 25 for clarity of illustration. The membraneplate 152 may be configured for mechanical coupling of a first end of the membraneplate with a pot, housing, etc. so that the coupled edge of the membraneplate is fixed and the membraneplate may operate in a reed-style configuration.

The membraneplate 152 may include one or more features for anisotropic reinforcement, in an embodiment, to account for the increased stress perpendicular to the axis of rotation of the membraneplate. For example, the membraneplate 152 may include a plurality of flanges 158. For clarity of illustration, not all flanges 158 are indicated in the figures. In an embodiment, the flanges may be disposed in the core layer 156. Accordingly, in an embodiment, the membraneplate 152 may include a core layer 156 having a foam matrix 160 and a plurality of flanges 158. Two or more of the flanges 158 may be parallel or substantially parallel to each other. In an embodiment, all of the flanges 158 may be parallel or substantially parallel with each other.

The flanges 158 may extend perpendicularly to the fixed edge of the membraneplate. Accordingly, the flanges 158 may extend perpendicularly to the rotational axis of the membraneplate. As a result, the flanges 158 may strengthen the membraneplate 152 (relative to known membraneplate configurations and designs) axially to compensate for the increased axial stress of a reed-style configuration.

The flanges 158 may comprise metal, in an embodiment. For example, the flanges 158 may comprise aluminum. In an embodiment, the flanges 158 may comprise the same material as one or more additional layers of the membraneplate 152. For example, the flanges 158 and two outer layers of the membraneplate 152 may comprise aluminum, in an embodiment.

One or more of the flanges 158 may comprise a continuous piece of monolithic material that extends along the entire length of the membraneplate 152, in an embodiment. Still further, in an embodiment, each of the flanges 158 may comprise a respective continuous piece of monolithic material that extends along the entire length of the membraneplate 152. Alternatively, one or more of the flanges 158 may comprise a piece of material that extends along only a portion of the length of the membraneplate 152.

In addition to, or as an alternative to flanges 158, the membraneplate 152 may include anisotropic reinforcement through a plurality of smaller pieces of material that extend generally perpendicular to the axis of rotation of the membraneplate. For example, in an embodiment, the core layer 156 of the membraneplate 152 may include a plurality of fibers that are generally oriented perpendicular to the axis of rotation. The fibers may comprise metal, in an embodiment, and/or another appropriate material.

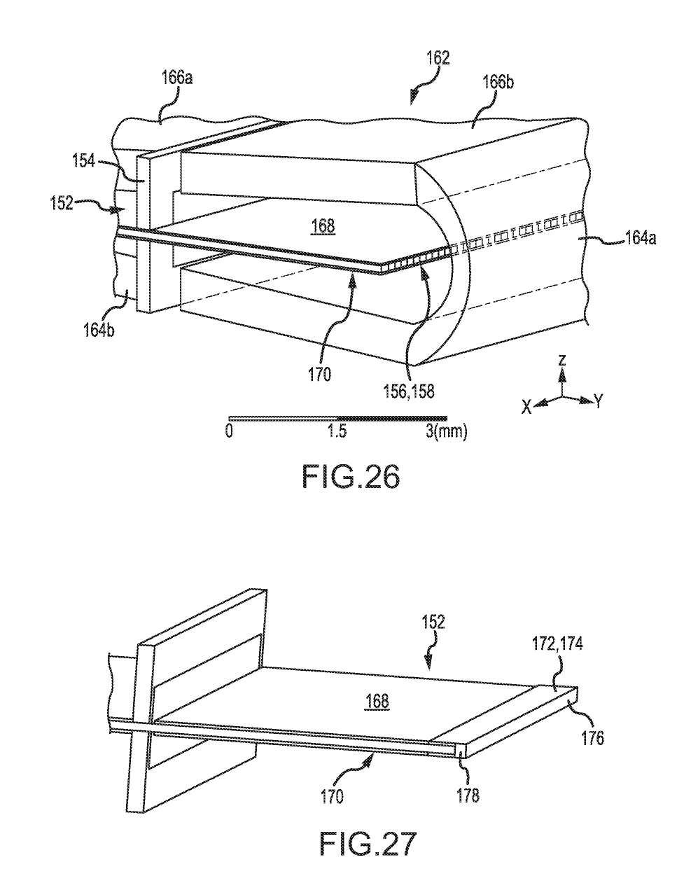

FIG. 26 is a partial isometric view of the membraneplate 152 partially illustrated in and described with respect to FIG. 25, and a coil 154 in a reed-style rotary flux transducer assembly 162. The assembly may include two pot portions 164a, 164b and two magnet portions 166a, 166b in addition to the membraneplate 152 and the coil 154. The membraneplate 152 may include a core layer 156 having a plurality of flanges 158. The membraneplate 152 may further include two outer layers 168, 170. The outer layers 168, 170 and core layer 156 may be arranged sequentially (i.e., with the core layer 156 in the middle) along the central axis A of the membraneplate 152. Of course, a membraneplate having anisotropic reinforcement as described and illustrated herein may find use with additional arrangements of pots, magnets, coils, etc. including, but not limited to, those arrangements illustrated and/or described herein.

In addition to support throughout the length of the membraneplate to account for increased stress along the length of the membraneplate perpendicular to the axis of rotation (e.g., in the form of flanges, fibers, etc.), additional structural support may be provided at particular points on the membraneplate to account for the different stresses inherent in a reed-style configuration. For example, in an embodiment, the fixed edge of the membraneplate may be provided additional support by its fixation to the remainder of the assembly. The center of the membraneplate may be provided additional support by the coil and/or a bobbin on which the coil is wound, for example. Furthermore, referring to FIG. 27, a cap 172 may be provided on the free end of the membraneplate 152 for additional support.

The cap 172 may comprise a U-shaped structure, in an embodiment, as shown in FIG. 27. The cap may comprise a plurality of faces, each of which may be formed by a sheet of material, that are generally parallel with respective surfaces of the membraneplate core layer or outer layers, in an embodiment. For example, the cap may include an upper face 174 that is generally parallel with a first outer layer 168 of the membraneplate 152 and that covers a portion of the first outer layer 168 of the membraneplate 152. The cap 172 may further include a lower face (not visible in FIG. 27) that is similarly parallel to and covers a second outer layer 170 of the membraneplate. The cap may further comprise an end face 176 that is generally parallel with the face of the free edge of the membraneplate, or otherwise perpendicular to the first and/or second outer layers 168, 170 of the membraneplate. Still further, the cap 172 may comprise a first side face 178 and a second side face (hidden from view in FIG. 27, but mirroring first side face 178, in an embodiment) that are generally parallel with the lateral edges of the membraneplate or otherwise perpendicular to one or both of the upper and lower faces of the cap 172 and/or the end face of the cap 172.

The multiple sheets/faces of the cap 172 may be formed from a single, monolithic body of material, in an embodiment. Alternatively, the cap 172 may be formed from multiple pieces of material. The cap 172 may be or may include a metal, in an embodiment, such as aluminum, for example only. In an embodiment, the cap 172 may be or may include the same material as flanges, fibers, or other structures providing anisotropic support for the membraneplate.

Various embodiments are described herein to various apparatuses, systems, and/or methods. Numerous specific details are set forth to provide a thorough understanding of the overall structure, function, manufacture, and use of the embodiments as described in the specification and illustrated in the accompanying drawings. It will be understood by those skilled in the art, however, that the embodiments may be practiced without such specific details. In other instances, well-known operations, components, and elements have not been described in detail so as not to obscure the embodiments described in the specification. Those of ordinary skill in the art will understand that the embodiments described and illustrated herein are non-limiting examples, and thus it can be appreciated that the specific structural and functional details disclosed herein may be representative and do not necessarily limit the scope of the embodiments, the scope of which is defined solely by the appended claims.

Reference throughout the specification to “various embodiments,” “some embodiments,” “one embodiment,” or “an embodiment”, or the like, means that a particular feature, structure, or characteristic described in connection with the embodiment is included in at least one embodiment. Thus, appearances of the phrases “in various embodiments,” “in some embodiments,” “in one embodiment,” or “in an embodiment”, or the like, in places throughout the specification are not necessarily all referring to the same embodiment. Furthermore, the particular features, structures, or characteristics may be combined in any suitable manner in one or more embodiments. Thus, the particular features, structures, or characteristics illustrated or described in connection with one embodiment may be combined, in whole or in part, with the features structures, or characteristics of one or more other embodiments without limitation given that such combination is not illogical or non-functional.

Although numerous embodiments of this invention have been described above with a certain degree of particularity, those skilled in the art could make numerous alterations to the disclosed embodiments without departing from the spirit or scope of this disclosure. All directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of the any aspect of the disclosure. As used herein, the phrased “configured to,” “configured for,” and similar phrases indicate that the subject device, apparatus, or system is designed and/or constructed (e.g., through appropriate hardware, software, and/or components) to fulfill one or more specific object purposes, not that the subject device, apparatus, or system is merely capable of performing the object purpose. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other. It is intended that all matter contained in the above description or shown in the accompanying drawings shall be interpreted as illustrative only and not limiting. Changes in detail or structure may be made without departing from the spirit of the invention as defined in the appended claims.

Any patent, publication, or other disclosure material, in whole or in part, that is said to be incorporated by reference herein is incorporated herein only to the extent that the incorporated materials does not conflict with existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

What is claimed is:

1. An acoustic transducer assembly comprising:
an acoustic membraneplate having an upper surface, a lower surface, a first radial edge and a second radial edge opposite the first radial edge;
an upper magnet and a lower magnet, the upper magnet being disposed above the upper surface of the membraneplate and the lower magnet being disposed below the lower surface of the membraneplate, wherein the membraneplate, the upper magnet and the lower magnet are oriented in substantially parallel planes and have similar transverse cross-sectional dimensions;
a first magnetic flux conductor and a second magnetic flux conductor, the first magnetic flux conductor disposed on the first radial edge of the membraneplate and the second magnetic flux conductor disposed on the second radial edge of the membraneplate, the magnetic flux conductors configured to conduct a magnetic flux between the magnets in a rotary path around the membraneplate;
a first coil coupled to the first radial edge of the membraneplate and configured to move with the membraneplate, the first coil disposed in an air gap between the first magnetic flux conductor and the magnets; and
a second coil coupled to the second radial edge of the membraneplate and configured to move with the membraneplate, the second coil disposed in an air gap between the second magnetic flux conductor and the magnets.

2. An acoustic transducer assembly comprising:
an acoustic membraneplate having an upper surface, a lower surface, a first radial edge and a second radial edge opposite the first radial edge;
an upper magnet and a lower magnet, the upper magnet being disposed above the upper surface of the membraneplate and the lower magnet being disposed below the lower surface of the membraneplate, wherein the membraneplate, the upper magnet and the lower magnet have similar transverse cross-sectional dimensions, and wherein the upper magnet and lower magnet are arranged in a non-parallel configuration, wherein the magnets are closer to each other nearer the first radial edge of the membraneplate than they are nearer the second radial edge of the membraneplate;
a first magnetic flux conductor disposed on the first radial edge of the membraneplate;
a second magnetic flux conductor disposed on the second radial edge of the membraneplate, wherein the first and second magnetic flux conductors are configured to conduct a magnetic flux between the magnets in a rotary path around the membraneplate; and
a coil coupled to the second radial edge of the membraneplate and disposed in an air gap between the second magnetic flux conductor and the magnets, the coil configured to move with the membraneplate;
wherein the first radial edge of the membraneplate is fixed relative to the first magnetic flux conductor and the membraneplate is configured to pivot about the first radial edge.

3. An acoustic transducer assembly comprising:
an acoustic membraneplate having an upper surface, a lower surface, a first radial edge and a second radial edge opposite the first radial edge;
a magnet disposed above the upper surface of the membraneplate and arranged in a first plane, the magnet having a length along one edge similar to the length of the membraneplate along the first radial edge;
a first magnetic flux conductor disposed on the first radial edge of the membraneplate, the first magnetic flux conductor comprising:
a planar portion arranged below the lower surface of the membraneplate, wherein the planar portion and the magnet are arranged in a non-parallel configuration and the planar portion is closer to the magnet nearer the first radial edge of the membraneplate than the second radial edge of the membraneplate; and
a first connection portion fixed to the planar portion and configured to conduct a magnetic flux between the magnet and the planar portion around the first radial edge of the membraneplate; and
a second magnetic flux conductor disposed on the second radial edge of the membraneplate, comprising a second connection portion configured to conduct a magnetic flux between the planar portion of the first magnetic flux conductor and the magnet around the second radial edge of the membraneplate;
wherein the magnet and the first and second magnetic flux conductors are configured to conduct a magnetic flux in a rotary path around the membraneplate; and
a coil coupled to the membraneplate at a fixed distance from the first radial edge, the coil disposed in an air gap between the magnet and the second magnetic flux conductor above the upper surface of the membraneplate, and between the planar portion and the second magnetic flux conductor below the lower surface of the membraneplate;
wherein the first radial edge of the membraneplate is fixed relative to the first magnetic flux conductor and the membraneplate is configured to pivot about an axis substantially parallel with the first radial edge.

4. An acoustic transducer assembly comprising:
a magnetic flux assembly comprising:
a first member comprising a magnet; and
a second member comprising one of a magnet and a magnetic flux conductor,
wherein the magnetic flux assembly generates a magnetic flux and the first member and second member are arranged such that the magnetic flux is conducted in a rotary path;
an acoustic membraneplate disposed between the first member and the second member and arranged such that the rotary path of the magnetic flux is around the membraneplate; and
at least one coil coupled to the membraneplate and configured to move with the membraneplate.

5. The acoustic transducer assembly of claim 4, wherein the membraneplate further comprises a suspension member along its peripheral edges, the suspension member configured to separate an air volume disposed above the membraneplate from an air volume disposed below the membraneplate.

6. The acoustic transducer assembly of claim 4, wherein the coil extends above an upper axial surface of the membraneplate and below a lower axial surface of the membraneplate.

7. The acoustic transducer assembly of claim 5, the magnetic flux assembly further comprising:
a first air gap between the first member and the second member located above the upper axial surface of the membraneplate; and
a second air gap between the first member and the second member located below the lower axial surface of the membraneplate,
wherein the coil is disposed within the first air gap and the second air gap.

8. The acoustic transducer assembly of claim 4, wherein the first member further comprises a magnetic flux conductor and the second member comprises at least one magnet and at least one magnetic flux conductor.

9. The acoustic transducer assembly of claim 8, wherein the magnet of the first member is disposed above an upper surface of the membraneplate and the magnet of the second member is disposed below a lower surface of the membraneplate.

10. The acoustic transducer assembly of claim 9, wherein the magnetic flux conductor of the first member is disposed on a first radial edge of the membraneplate and the magnetic flux conductor of the second member is disposed on a second radial edge of the membraneplate opposite the first radial edge.

11. The acoustic transducer assembly of claim 8, wherein at least one of the magnetic flux conductors comprises a crescent-shaped body.

12. The acoustic transducer assembly of claim 8, wherein the direction of the magnetic flux induced by the magnet of the second member is in the same rotary direction as the magnetic flux induced by the magnet of the first member.

13. The acoustic transducer assembly of claim 4, wherein the membraneplate comprises a first radial edge and a second radial edge opposite the first radial edge, and wherein the coil is coupled to the second radial edge of the membraneplate.

14. The acoustic transducer assembly of claim 13, wherein the coil is a first coil and the transducer assembly further comprises a second coil coupled to the first radial edge of the membraneplate.

15. The acoustic transducer assembly of claim 4, wherein the membraneplate comprises a first radial edge and a second radial edge opposite the first radial edge, and wherein the coil is coupled to the membraneplate at a location between the first radial edge and the second radial edge.

16. The acoustic transducer assembly of claim 15, wherein the coil surrounds the membraneplate and is arranged in a plane that is generally parallel with the first radial edge of the membraneplate.

17. The acoustic transducer assembly of claim 4, wherein at least a portion of the first member is crescent shaped and at least a portion of the second member is crescent shaped.

18. The acoustic transducer assembly of claim 4, wherein at least one radial edge of the acoustic membrane plate is coupled to the magnetic flux assembly via a suspension member.

19. The acoustic transducer assembly of claim 18, wherein all radial edges of the acoustic membrane plate are coupled to the magnetic flux assembly via suspension members, the suspension members configured to separate an air volume disposed above the membraneplate from an air volume disposed below the membraneplate.

20. The acoustic transducer assembly of claim 4, wherein the magnet of the first member is a permanent magnet.

21. The acoustic transducer assembly of claim 4, wherein the coil comprises one or more turns, each turn substantially perpendicular to the surface of the membraneplate.

22. The acoustic transducer assembly of claim 4, further comprising a housing configured to retain the magnetic flux assembly, the acoustic membraneplate and the coil.

23. The acoustic transducer assembly of claim 22, wherein the housing contains one or more indentations configured to receive one or more portions of the magnetic flux assembly.

24. The acoustic transducer assembly of claim 23, wherein at least a portion of the first member is crescent shaped and at least a portion of the second member is crescent shaped, wherein the housing contains at least two crescent-shaped indentations configured to receive the crescent-shaped portions of the first and second members.

25. The acoustic transducer assembly of claim 22, wherein the housing comprises one or more air ports configured to allow the entry and exit of air from a surface of the membraneplate.

26. The acoustic transducer assembly of claim 22, wherein at least one radial edge of the acoustic membraneplate is coupled to the housing via a suspension member.

27. The acoustic transducer assembly of claim 26, wherein all radial edges of the acoustic membraneplate are coupled to the housing via a suspension member.

28. The acoustic transducer assembly of claim 22, wherein the acoustic transducer assembly is configured such that an air volume disposed above an upper surface of the membraneplate is isolated from an air volume disposed below a lower surface of the membraneplate.

29. The acoustic transducer assembly of claim 4, further comprising an electrical circuit disposed on the surface of the membraneplate.

30. The acoustic transducer assembly of claim 29, wherein the electrical circuit comprises a class D amplifier electrically coupled to the at least one coil.

31. The acoustic transducer assembly of claim 30, further comprising an electrical output damping component disposed on an edge of the membraneplate and electrically coupled between the class D amplifier and the coil.

32. The acoustic transducer assembly of claim 4, wherein the membraneplate comprises a first radial edge and a second radial edge opposite the first radial edge, and wherein the first radial edge is fixed relative to the first member, the membraneplate being configured to pivot about an axis substantially parallel with the first radial edge.

33. The acoustic transducer assembly of claim 32, wherein the coil is coupled to the second radial edge of the membraneplate.

34. The acoustic transducer assembly of claim 33, wherein the membraneplate further comprises at least a third radial edge, the third radial edge being coupled to the magnetic flux assembly via a suspension member.

35. The acoustic transducer assembly of claim 32, wherein the coil is coupled to the membraneplate at a location between the first radial edge and the second radial edge.

36. The acoustic transducer assembly of claim 35, wherein the second radial edge of the membrane plate is coupled to the magnetic flux assembly via a suspension member.

37. The acoustic transducer assembly of claim 36, wherein the membraneplate further comprises at least a third radial edge, and all further radial edges are also coupled to the magnetic flux assembly via a suspension member.

38. The acoustic transducer assembly of claim 32, wherein the membraneplate comprises:
a core layer;
two outer layers disposed on opposed surfaces of the core layer; and
a plurality of support members disposed within the core layer, between the two outer layers and oriented longitudinally between the first radial edge and the second radial edge.

39. The acoustic transducer assembly of claim 38, wherein a cap is disposed on the second radial edge of the membraneplate, the cap configured to provide structural support to the second radial edge of the membraneplate.

40. The acoustic transducer assembly of claim 32, further comprising:
an electrical connection disposed on the membraneplate near the first radial edge and between the first radial edge and the at least one coil; and
an electrical pathway between the electrical connection and the at least one coil, wherein the coil is electrically coupled to circuitry outside the acoustic transducer assembly via the electrical connection.

41. The acoustic transducer assembly of claim 40, wherein the electrical pathway is comprised of one of printed circuits, conduits or secured wire.

42. The acoustic transducer assembly of claim 4, wherein the coil comprises a first coil mechanically coupled to a second coil, the first and second coils each formed by a plurality of loops and comprising:
a substantially planar portion along substantially its entire length; and
a generally off-plan portion configured at an angle from the planar portion located on one end of the coil;
wherein the off-plane portions are configured to allow the first and second coils to fit together such that the planar portions of each coil are located in substantially the same plane.

43. The acoustic transducer assembly of claim 40, wherein the first and second coils are arranged within the magnetic flux path asymmetrically relative to each other.

44. The acoustic transducer assembly of claim 39, wherein the planar portions of the first and second coils are in a plane substantially transverse to the magnetic flux rotary path.

45. An acoustic transducer assembly comprising:
a membraneplate having a central axis, an upper axial surface, and a lower axial surface;
a coil, mechanically coupled to the membraneplate so as to move with the membraneplate, the coil extending above the upper axial surface of the membraneplate and below the lower axial surface of the membraneplate.

46. The acoustic transducer assembly of claim 45, wherein the coil is a first coil, further comprising a second coil mechanically coupled with the membraneplate so as to move with the membraneplate.

47. The acoustic transducer assembly of claim 46, wherein the first coil and the second coil are mechanically coupled with opposing radial edges of the membraneplate.

48. An acoustic transducer assembly, comprising:
a magnet;
a coil; and
a membraneplate, mechanically coupled with the coil so that the coil is moveable relative to the magnet, wherein one edge of the membraneplate is fixed relative to the magnet and all remaining edges are movable relative to the magnet.

49. The acoustic transducer of claim 48, wherein the coil is attached to an edge of the membraneplate that is opposite the fixed edge of the membraneplate.

50. The acoustic transducer of claim 48, wherein the coil is attached to the membraneplate at a location between the fixed edge and an edge of the membraneplate that is opposite the fixed edge.

51. A voice coil assembly for an acoustic transducer assembly, the voice coil assembly comprising a first coil coupled to a second coil, each coil formed by a plurality of loops and comprising:
a substantially planar portion along substantially its entire length; and
a generally off-plan portion configured at an angle from the planar portion located on one end of the coil;
wherein the off-plane portions are configured to allow the coils to fit together such that the planar portions of each coil are located in substantially the same plane.

52. The voice coil assembly of claim 51, wherein the planar portion of each coil comprises a top and bottom portion, and wherein the coils are configured to fit together such that, within the plane in which the planar portions are located, the top portion of the first coil is on top, followed by the top portion of the second coil, the bottom portion of the first coil and then the bottom portion of the second coil.

53. An acoustic membraneplate for use in an acoustic transducer assembly, the membraneplate comprising:
a core layer;
two outer layers disposed on opposed surfaces of the core layer; and
a plurality of support members longitudinally disposed within the core layer and between the two outer layers.

54. The acoustic membraneplate of claim 53, wherein the core layer is comprised of a foam matrix.

55. The acoustic membraneplate of claim 53, wherein at least one of the two outer layers is comprised of a laminated metal.

56. The acoustic membraneplate of claim 55, wherein both of the two outer layers are comprised of a laminated metal.

57. The acoustic membraneplate of claim 53, wherein the two outer layers have substantially the same dimensions.

58. The acoustic membraneplate of claim 53, wherein one or more of the plurality of support members is comprised of a metal.

59. The acoustic membraneplate of claim 58, wherein one or more of the plurality of support members and at least one of the two outer layers are comprised of the same material.

60. The acoustic membraneplate of claim 59, wherein all of the plurality of support members and the two outer layers are comprised of the same material.

61. The acoustic membraneplate of claim 53, wherein the plurality of support members comprises a plurality of flanges.

62. The acoustic membraneplate of claim 61, wherein the plurality of flanges are substantially parallel with each other.

63. The acoustic membraneplate of claim 61, wherein at least one of the plurality of flanges extends the entire length of the membraneplate.

64. The acoustic membraneplate of claim 63, wherein all of the plurality of flanges extend the entire length of the membraneplate.

65. The acoustic membraneplate of claim 53, wherein the plurality of support members comprises a plurality of fibers generally oriented in a longitudinal direction.

66. The acoustic membraneplate of claim 65, wherein the plurality of fibers are comprised of metal.

67. The acoustic membraneplate of claim 53, wherein the plurality of support members comprises a plurality of flanges substantially parallel with each other and a plurality of fibers generally oriented in a longitudinal direction.
